(19) United States
(12) Patent Application Publication
(10) Pub. No.: US 2026/0231509 A1
(43) Pub. Date: Aug. 6, 2026

(54) SEMICONDUCTOR DEVICE FABRICATION WITH INCREASED TRANSISTOR ISOLATION DENSITY

(71) Applicant: Taiwan Semiconductor Manufacturing Company, Ltd., Hsinchu (TW)

(72) Inventors: Tzu-Ging Lin, Kaohsiung (TW); Jian-Yu Chen, Taipei (TW)

(21) Appl. No.: 19/045,493

(22) Filed: Feb. 4, 2025

(51) Int. Cl. H10D 84/01; H01L 21/762; H10D 30/00; H10D 30/01; H10D 30/67; H10D 62/13; H10D 84/83

(52) U.S. Cl. CPC H10D 84/0153; H10D 30/0191; H10D 30/502; H10D 30/6735; H10D 62/151; H10D 84/013; H10D 84/832; H10W 10/014; H10W 10/17

(57) ABSTRACT

Techniques are described for semiconductor device fabrication with increased transistor isolation density by employing a combined cut metal gate (CMG) and epitaxial growth (EPI) patterning (CMGEP) technique to selectively disable transistors in a fabricated array. As described herein, such embodiments provide a larger etching window to avoid EPI damage (i.e., damage to surrounding source/drain structures), and larger margins for avoiding scum defects and photoresist peeling defects. In particular, rather than etching along (in line with) the metal gate line, CMGEP approaches remove a source/drain structure (before or after epitaxial growth) and cut perpendicularly across adjacent metal gate lines in one or more corresponding shallow trench isolation (STI) regions. Techniques are also described for selectively disabling transistors using gate threshold voltage differentiation and/or bottom isolation dielectric deposition.

### TECHNICAL FIELD

The present disclosure relates to semiconductor devices and, more particularly, to selective isolation of semiconductor devices, including nanosheet transistors, fin field effect transistors (FinFETs), and/or gate-all-around (GAA) field effect transistors (FETs), during semiconductor device fabrication.

### BACKGROUND

The semiconductor industry has experienced rapid growth due to continuous improvements in the integration density of a variety of electronic components (e.g., transistors, diodes, resistors, capacitors, etc.). For the most part, this improvement in integration density has come from repeated reductions in minimum feature size, which allows more components to be integrated into a given area. As minimum feature sizes continue to decrease, it can become increasingly difficult or impractical to reliably use conventional approaches for isolating and/or disabling transistors.

### BRIEF DESCRIPTION OF THE DRAWINGS

The present disclosure is best understood from the following detailed description when read with the accompanying figures. It is noted that, in accordance with the standard practice in the industry, various features are not drawn to scale and are used for illustration purposes only. In fact, the dimensions of the various features may be arbitrarily increased or reduced for clarity. Some sequences of related figures (e.g., illustrating sequential stages of a process) are labeled with the same figure number followed by an alphabetic character, such as FIGS. 25A, 25B, 25C, etc. For long sequences, certain alphabetic characters, such as ‘I’, ‘L’, and ‘O’, are skipped to avoid common optical character recognition errors.

FIG. 1A shows an example portion of a semiconductor device having an array of transistors implemented on a substrate.

FIG. 1B shows an illustrative portion of an X-directional cut through a shallow trench isolation (STI) region, such as corresponding to cross section ‘A’ of FIG. 1A.

FIG. 1C shows an illustrative portion of an X-directional cut through a transistor region, such as corresponding to cross section ‘B’ of FIG. 1A.

FIG. 1D shows an illustrative portion of a Y-directional cut through a transistor region, such as corresponding to cross section ‘C’ of FIG. 1A.

FIG. 1E shows an illustrative portion of a Y-directional cut through an EPI region, such as corresponding to cross section ‘D’ of FIG. 1A.

FIGS. 2A-2D demonstrate example issues that can result from certain etching, such as CPODE etching, as transistor structure sizes decrease.

FIG. 3A shows a top-down view of a portion of a semiconductor device having an array of transistors formed thereon.

FIG. 3B shows another top-down view of the same portion of the semiconductor device with transistors and disabled using a first illustrative CMGEP approach.

FIG. 3C shows another top-down view of the same portion of the semiconductor device with transistors and disabled using a second illustrative CMGEP approach.

FIGS. 4A-4E represent transistor isolation using an illustrative CMGEP approach in which EPI patterning is performed before EPI growth.

FIGS. 5A-5D represent transistor isolation using an illustrative CMGEP approach in which EPI patterning is performed after EPI growth.

FIG. 6 shows an illustrative portion of an X-directional cut through a transistor region of the semiconductor device after using illustrative CMGEP approaches in which EPI patterning is performed after EPI growth, such as corresponding to that of FIG. 5B.

FIG. 7 shows another illustrative portion of an X-directional cut through a transistor region of the semiconductor device after using illustrative CMGEP approaches in which EPI patterning is performed after EPI growth, similar to that of FIG. 5B.

FIG. 8 shows a first T-shaped CMGEP transistor isolation scheme used to remove one source/drain structure from a semiconductor device, thereby disabling two transistors.

FIG. 9 shows a second I-shaped CMGEP transistor isolation scheme used to remove one source/drain structure from a semiconductor device, thereby disabling two transistors.

FIG. 10 shows a third I-shaped CMGEP transistor isolation scheme used to remove one source/drain structure from a semiconductor device, thereby disabling two transistors.

FIG. 11 shows a second T-shaped CMGEP transistor isolation scheme used to remove one source/drain structure from a semiconductor device, thereby disabling two transistors.

FIG. 12 shows a fourth I-shaped CMGEP transistor isolation scheme used to remove one source/drain structure from a semiconductor device, thereby disabling two transistors.

FIGS. 13A and 13B show a comparison of pitch size between CPODE-type and EPI patterning-based transistor isolation approaches.

FIGS. 14A and 14B show top-down views of a comparison between CPODE-type and EPI patterning-based transistor isolation approaches, respectively, for enabling a single active line of transistors.

FIGS. 15A and 15B show top-down views of a comparison between CPODE-type and EPI patterning-based transistor isolation approaches, respectively, for enabling two active lines of transistors.

FIGS. 16A and 16B show top-down views of a comparison between CPODE-type and EPI patterning-based transistor isolation approaches, respectively, for enabling three active lines of transistors.

FIGS. 17A and 17B show top-down views of a comparison between CPODE-type and EPI patterning-based transistor isolation approaches, respectively, for disabling two columns of transistors.

FIGS. 18A and 18B show top-down views of a comparison between CPODE-type and EPI patterning-based transistor isolation approaches, respectively, for disabling three columns of transistors.

FIGS. 19A and 19B show top-down views of a comparison between CPODE-type and EPI patterning-based transistor isolation approaches, respectively, for disabling four columns of transistors.

FIGS. 20A-20C show top-down views of a comparison between CPODE-type and two different EPI patterning-based transistor isolation approaches, respectively, for disabling five columns of transistors.

FIGS. 21A and 21B show top-down views of a comparison between CPODE-type and EPI patterning-based transistor isolation approaches, respectively, for disabling two columns of transistors in an estuary.

FIGS. 22A and 22B show top-down views of a comparison between CPODE-type and EPI patterning-based transistor isolation approaches, respectively, for disabling four columns of transistors in an estuary.

FIGS. 23A-23U illustrate a sequence of stages of a nanosheet transistor fabrication process including EPI patterning before EPI growth, according to some embodiments described herein.

FIGS. 24A-24H illustrate a sequence of stages of a nanosheet transistor fabrication process including selectively removing epitaxially grown source/drain structures prior to metal gate deposition (during front end of line, FEOL), according to some embodiments described herein.

FIGS. 25A-25H illustrate a sequence of stages of a nanosheet transistor fabrication process including selectively removing epitaxially grown source/drain structures subsequent to metal gate deposition (during middle end of line, MEOL), according to some embodiments described herein.

FIGS. 26A-26E illustrate a sequence of stages of a nanosheet transistor fabrication process including a application of cut metal gate techniques, according to some embodiments described herein.

FIG. 27 shows a flow diagram of an illustrative method, according to embodiments described herein.

FIG. 28A-29B show examples of transistors with different channel lengths patterned using CPODE or CMODE techniques.

FIG. 30 shows a cross-sectional view before gate-etching and a corresponding cross-sectional view after gate-etching.

FIG. 31 shows an example of transistor isolation by gate differentiation, according to some embodiments described herein.

FIGS. 32A-32G show selected stages of a fabrication process for creating gate structures with different threshold voltages, according to embodiments described herein.

FIGS. 33A-33P illustrate a sequence of stages of a semiconductor device fabrication process including gate differentiation and bottom isolation dielectric deposition, according to some embodiments described herein.

FIGS. 34A-34C show a portion of a fabrication process corresponding to FIGS. 33M-33P, respectively, as applied to a long-channel device.

FIG. 35 shows an illustrative embodiment in which a CMODE process is combined with novel gate differentiation and bottom isolation approaches described herein.

FIG. 36 shows an illustrative embodiment in which a CPODE process is combined with novel gate differentiation and bottom isolation approaches described herein.

FIGS. 37A and 37B show an example of metal boundary regions forming as part of gate differentiation approaches described herein and use of cut metal gate approaches to remove such regions.

FIGS. 38A-38F illustrate a sequence of stages of a cut metal gate process to remove metal boundary regions, such as described with reference to FIGS. 37A and 37B.

FIG. 39 shows a flow diagram of an illustrative method for partially fabricating a semiconductor device including gate differentiation and bottom isolation dielectric deposition, according to some embodiments described herein.

### DETAILED DESCRIPTION

The present disclosure provides many different embodiments, or examples, for implementing different features of the provided subject matter. Embodiments disclosed herein are merely examples and are not intended to be limiting. For example, dimensions of elements are for illustration only and should not be construed to limit ranges or values of those dimensions in accordance with the disclosure. Specific examples of components and arrangements are described below to simplify the present disclosure. These are, of course, merely examples and are not intended to be limiting. The present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper,” “top,” “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. The term “horizontal” is defined as a plane parallel to the conventional plane or main surface of a wafer or substrate, regardless of the orientation of the wafer or substrate. The term “vertical” refers to a direction perpendicular to the horizontal as defined above. It will be understood that, although the terms “first,” “second,” “third,” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present disclosure.

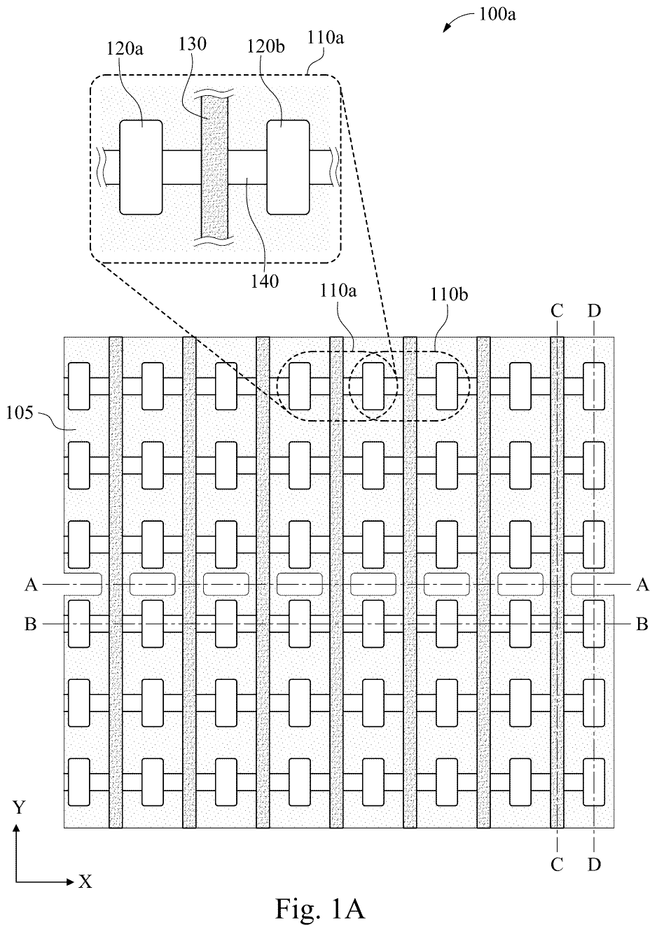

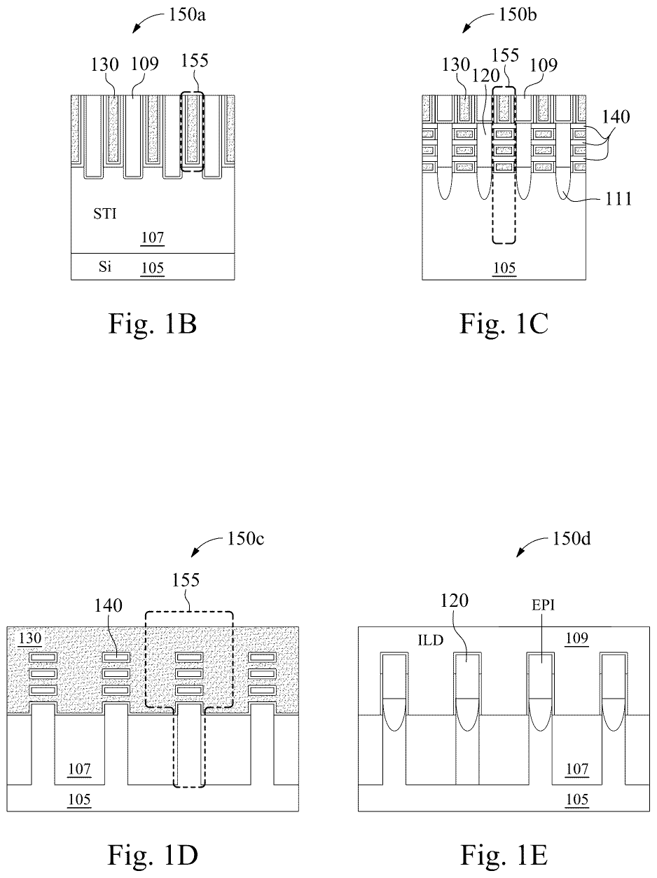

In general, the present disclosure provides various embodiments of manufacturing techniques involving semiconductor devices that include a number of transistors. FIG. 1A shows an example portion of a semiconductor device 100a having an array of transistors 110 implemented on a substrate 105. The substrate 105 may be a semiconductor substrate, such as a bulk semiconductor, a semiconductor-on-insulator (SOI) substrate, or the like, which may be doped (e.g., with a p-type or an n-type dopant) or undoped. The substrate 105 may be a wafer, such as a silicon wafer. Generally, an SOI substrate includes a layer of a semiconductor material formed on an insulator layer (not shown). The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 105 may include silicon; germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof.

Such a semiconductor device can have very large numbers of transistors 110. In one example, such a semiconductor device has hundreds of billions of transistors 110. As illustrated, the semiconductor device 100a includes an array of source/drain structures 120. Each source/drain structure 120 is an epitaxial structure that can perform as a source or a drain when operating as part of a corresponding transistor 110. The source/drain structures 120 are disposed on linear channel regions 140, and the channel regions 140 are activated by metal gate lines 130. The metal gate lines 130 run in a direction perpendicular to that of the channel regions 140.

As illustrated, each transistor 110 is made up of a pair of source/drain structures 120 separated by a respective portion of one of the linear channel regions 140 and activated by a respective portion of one of the metal gate lines 130. For example, transistor 110a is illustrated with its corresponding pair of source/drain structures 120a, 120b separated by its respective portion of one of the linear channel regions 140 and activated by its respective portion of one of the metal gate lines 130. For further clarity and context, four cross sections are labeled ‘A’, ‘B’, ‘C’, and ‘D’. These cross sections represent an X-directional cut through a shallow trench isolation (STI) region, an X-directional cut through a transistor (e.g., fin-FET) region, a Y-directional cut through a transistor region, and a Y-directional cut through an epitaxial structure (EPI) region, respectively. These cross-sections are illustrated in FIGS. 1B-1D .

FIG. 1B shows an illustrative portion of an X-directional cut 150a through a shallow trench isolation (STI) region, such as corresponding to cross section ‘A’ of FIG. 1A. The cross-section shows the silicon (Si) substrate 105 covered by an STI layer 107. Formed and patterned on top of the STI layer 107 are several metal gate lines 130 separated by interlayer dielectric (ILD) material 109.

FIG. 1C shows an illustrative portion of an X-directional cut 150b through a transistor region, such as corresponding to cross section ‘B’ of FIG. 1A. The cross-section shows the substrate 105. In this region, there is no STI layer 107. Formed and patterned on top of the substrate 105 are regions alternating between source/drain regions and gate/channel regions. Each source/drain region includes a source/drain structure 120 covered by ILD material 109. Each gate/channel region includes one or more layers of channel material forming a linear channel region 140 and a metal gate line 130 disposed above the linear channel region 140. For example, activating one of the metal gate lines 130 causes current to flow through the linear channel region 140 below the activated metal gate line 130, thereby flowing between the source/drain structures 120 on either side of the linear channel region 140. In some implementations, a bottom layer 111 is formed below the source/drain structures 120. In some such implementations, the bottom layer 111 is a buffer layer (e.g., of pure silicon) to help facilitate epitaxial growth of the source/drain structures 120. In other such implementations, the bottom layer 111 is a bottom isolation layer to help prevent leakage current between adjacent source/drain structures 120.

FIG. 1D shows an illustrative portion of a Y-directional cut 150c through a transistor region, such as corresponding to cross section ‘C’ of FIG. 1A. The cross-section shows the substrate 105 and STI layer 107. The illustrated transistor includes fin-FETs. Thus, the cross-section shows the linear channel regions 140 (formed by one or more layers of channel material) surrounded on three sides by the material of the metal gate line 130.

FIG. 1E shows an illustrative portion of a Y-directional cut 150d through an EPI region, such as corresponding to cross section ‘D’ of FIG. 1A. The cross-section shows the substrate 105 and STI layer 107. Several source/drain structures 120 are shown epitaxially grown above the substrate 105 and separated by ILD material 109.

In a typical scenario, a large array of transistors 110 is manufactured, and processes are used to “disable” or isolate selected ones of the transistors 110 to form circuits. To disable a particular transistor 110, some conventional techniques cut the substrate 105 at the location of the respective portion of the metal gate line 130 for that transistor 110 so that the transistor 110 cannot be activated. The cuts can be filled with a dielectric material to electrically isolate transistors 110 from one another. For example, dashed region 155 in FIGS. 1B, 1C, and 1D illustrate an example metal gate line 130 region that can be cut and filled to effectively disable a transistor 110 according to such conventional techniques.

Due to overlap or shift, certain etching processes can cause damage to the epitaxial structure of the transistor(s) 110, such as during the patterning process. Some conventional techniques implement a directional etching profile and/or an etching process that utilizes different etching parameters when etching at different depths through the transistor devices, and/or when etching different materials or structures of the transistor devices. For example, a cut polysilicon on diffusion edge (CPODE) technique can be used to cut the substrate 105 at the location of the respective portion of the metal gate line 130 for that transistor 110. In some cases, the CPODE process is used if prior to forming the metal gate at the respective portion of the metal gate line 130, and a cut metal on diffusion edge (CMODE) process is used if subsequent to forming the metal gate at the respective portion of the metal gate line 130.

For added context, examples of CPODE processes are described. Such processes can be used, for example, to form transistor 110 devices, such as a nanosheet transistor devices, fin field-effect transistor (FinFET) devices, nanowire transistor devices, vertical transistor devices, or the like, and to electrically isolate the transistor devices from one another according to a predetermined design using CPODE techniques. The CPODE process can begin by forming layers on the substrate 105. Layers can be etched and dielectrics can be deposited. In some cases, a chemical mechanical polish (CMP) procedure is used and dielectrics are etched. The process can then involve depositing sacrificial material, hardmasks, and dielectric material. Again, the dielectric can be etched. A high-k dielectric can be deposited, and another CMP process can be performed. The sacrificial material can be etched. Another dielectric layer can be deposited, followed by depositing a polysilicon (PO) material, hardmasks, and spacer material. The process can then involve vertically etching the material structure and forming spacers. Semiconductor material can be epitaxially grown, after which an interlayer dielectric (ILD) and a contact etch stop layer (CESL) can be formed and another CMP process can be performed. Hardmasks and photoresist ca nbe deposited. CPODE etching can be used to etch the hardmasks and PO and to further etch through one or more layers. At least one protection layer can be deposited, and the protection layer(s) can be etched. CPODE etching can then be used to etch through the substrate 105. Again, dielectric can be deposited and a CMP process can be performed.

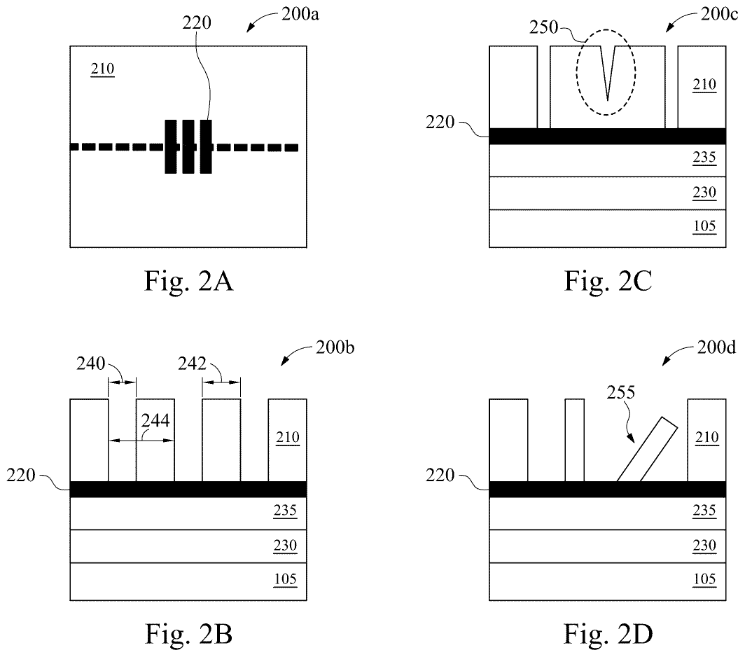

Although CPODE and other conventional techniques can be effective, they can tend to become less reliable as transistor structure sizes decrease. FIGS. 2A-2D demonstrate example issues that can result from certain etching, such as CPODE etching, as transistor structure sizes decrease. FIG. 2A shows a top-down view 200a of an example portion of a semiconductor device. A photoresist layer 210 covers the surface of the semiconductor device, except where the photoresist layer 210 has been etched (e.g., using CPODE etching) to reveal an oxide middle layer 220 beneath. For example, the CPODE etching has been performed to cut away portions of three adjacent metal gate lines. A cross-section ‘A’ is shown.

FIG. 2B shows a first partial view 200b through cross-section ‘A’ of FIG. 2A at the location of the cuts in the photoresist layer 210. For added context, the cross-sectional view shows (from bottom to top) a substrate 105 layer, a hard mask layer 230 (e.g., silicon nitride), a carbon bottom layer 235, the oxide middle layer 220, and the etched photoresist layer 210. As illustrated, the etching dimension that dictates the size (e.g., width) of the opening can be referred to as the “after-development-inspection critical dimension” (ADI CD) 240. Between each two adjacent openings, a section of the photoresist layer 210 remains, so that the remaining section has a dimension (e.g., width) referred to as the “spacing” 242. Each ADI CD 240 and adjacent spacing 242 can together constitute a “pitch size” 244. In general, CPODE and other such techniques tend to work well when the ADI CD 240 is close to half of the pitch size 244.

FIG. 2C shows a second partial view 200c through cross-section ‘A’ of FIG. 2A at the location of the cuts in the photoresist layer 210. The second partial view 200c corresponds to the same region as the first partial view 200b in FIG. 2B, except with different etching dimensions. In particular, FIG. 2C shows a condition in which the ADI CD 240 is much less than the spacing 242. As illustrated, this can result in a condition referred to as a “scum defect” 250, in which the etching is effectively incomplete in some locations.

FIG. 2D shows a third partial view 200d through cross-section ‘A’ of FIG. 2A at the location of the cuts in the photoresist layer 210. The third partial view 200d corresponds to the same region as the first partial view 200b in FIG. 2B and the second partial view 200c in FIG. 2C, except with different etching dimensions. In particular, FIG. 2D shows a condition in which the ADI CD 240 is much greater than the spacing 242. As illustrated, this can result in a condition referred to as a “photoresist peeling” (or “PR peeling”) 255, in which remaining (unetched) portions of the photoresist layer 210 are so narrow that they can tend to lean, peel, or fall in some locations.

Based on the above, it can be seen that conventional techniques can result in undesirable effects as transistor features continue to decrease in size. As one example, FIG. 1C shows the metal gate line 130 region (designated by the dashed oval 155) intended to be removed by CPODE etching. If too much is removed to either side of the dashed oval 155, the adjacent source/drain structures 120 can be damaged. As another example, FIG. 2C shows how scum defects can occur. As another example, FIG. 2D shows how PR peeling defects can occur.

Embodiments described herein provide semiconductor device fabrication with increased transistor isolation density by employing a combined cut metal gate (CMG) and EPI patterning (CMGEP) technique to selectively disable transistors in a fabricated array. As described herein, such embodiments provide a larger etching window to avoid EPI damage (i.e., damage to surrounding source/drain structures 120), and larger margins for avoiding scum defects and PR peeling defects. In particular, rather than etching along (in line with) the metal gate line 130, CMGEP approaches remove a source/drain structure 120 (before or after epitaxial growth) and cut perpendicularly across adjacent metal gate lines 130 in one or more corresponding STI regions.

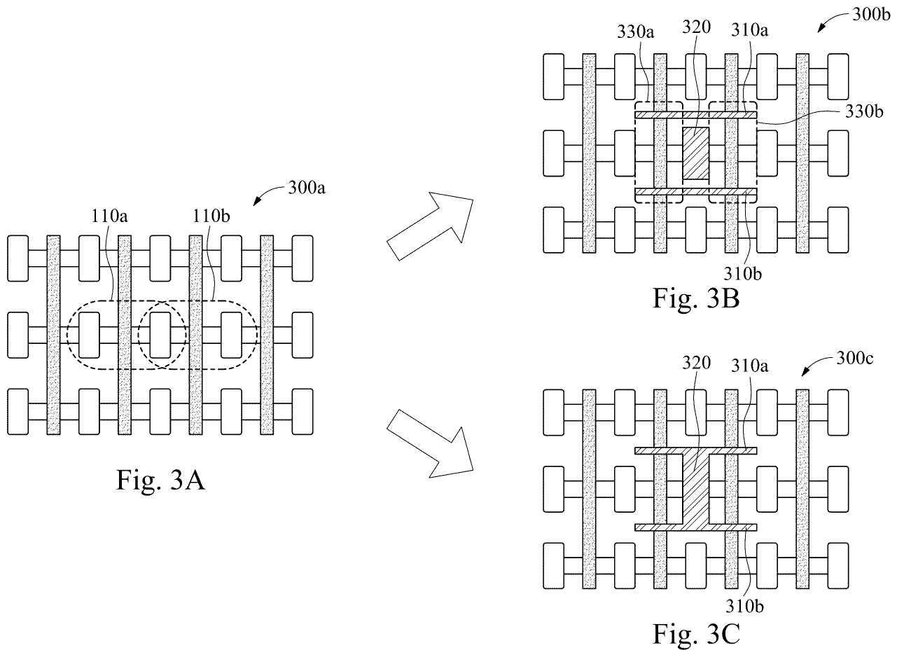

For the sake of illustration, FIGS. 3A-3C show examples of CMGEP techniques, as described herein. FIG. 3A shows a top-down view 300a of a portion of a semiconductor device having an array of transistors 110 formed thereon. As described above, each transistor 110 is made up of a pair of source/drain structures 120 lying on a portion of a linear channel region 140 and having a portion of a metal gate line 130 disposed therebetween and running substantially perpendicular to the linear channel region 140. Two transistors 110a and 110b are shown.

FIG. 3B shows another top-down view 300b of the same portion of the semiconductor device with transistors 110a and 110b disabled using a first illustrative CMGEP approach. As illustrated, first and second CMG cuts 310a and 310b are made to isolate corresponding segments of two of the metal gate lines 130 (shows in dashed ovals 330a and 330b), and an EPI removal 320 is performed on the one of the source/drain structures 120 shared by transistors 110a and 110b. Thus, transistors 110a and 110b are effectively disabled and/or isolated from the array.

FIG. 3C shows another top-down view 300c of the same portion of the semiconductor device with transistors 110a and 110b disabled using a second illustrative CMGEP approach. Similar to the implementation of FIG. 3B, first and second CMG cuts 310a and 310b are made to isolate corresponding segments of two of the metal gate lines 130, and an EPI removal 320 is performed on the one of the source/drain structures 120 shared by transistors 110a and 110b. However, in FIG. 3B, the EPI removal 320 is disconnected from the CMG cuts 310; while in FIG. 3C, the EPI removal 320 extends all the way to the CMG cuts 310. In both implementations, transistors 110a and 110b are effectively disabled and/or isolated from the array.

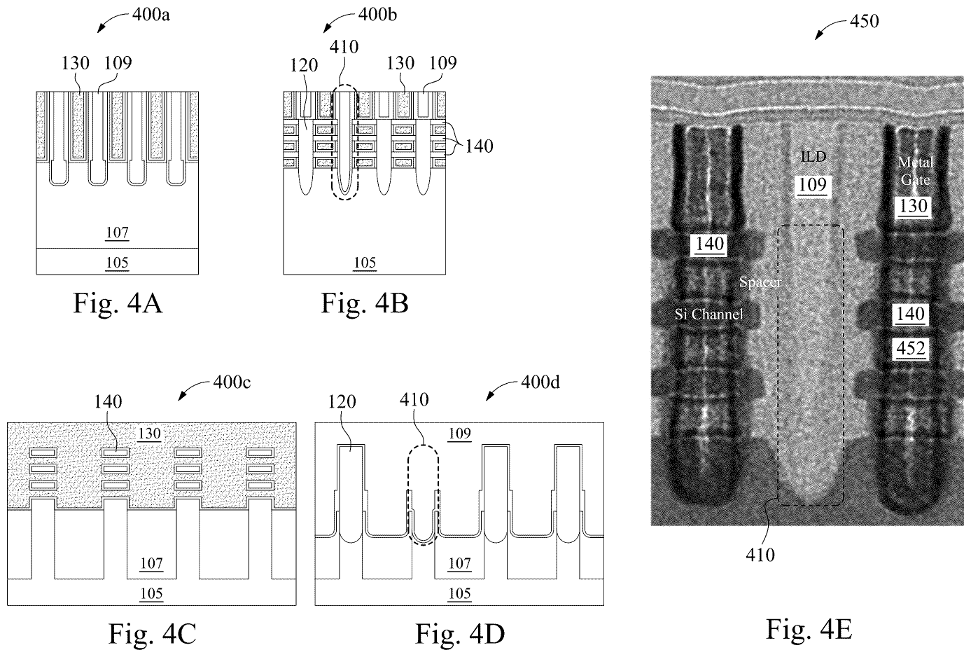

FIGS. 4A-4E represent transistor isolation using an illustrative CMGEP approach in which EPI patterning is performed before EPI growth. In particular, FIGS. 4A-4D represent an illustrative portion of an X-directional cut 400a through a shallow trench isolation (STI) region of a semiconductor device, such as corresponding to cross section ‘A’ of FIG. 1A; an illustrative portion of an X-directional cut 400b through a transistor region of the semiconductor device, such as corresponding to cross section ‘B’ of FIG. 1A; an illustrative portion of a Y-directional cut 400c through a transistor region of the semiconductor device, such as corresponding to cross section ‘C’ of FIG. 1A; and an illustrative portion of a Y-directional cut 400d through an EPI region of the semiconductor device, such as corresponding to cross section ‘D’ of FIG. 1A; respectively. The cross-sectional views 400 show only the EPI patterning, not the CMG.

Comparing FIGS. 4A-4D with FIGS. 1B-1E , it can be seen that the EPI patterning does not impact either the STI region in the X direction (i.e., FIG. 4A is unchanged relative to FIG. 1B) or the transistor region (the metal gate lines) in the Y direction (i.e., FIG. 4C is unchanged relative to FIG. 1D). However, an epitaxial source/drain structure 120 has been eliminated, as illustrated in the respective X-and Y-directional cross-sections 400b and 400d of FIGS. 4B and 4D. As illustrated, the area where the source/drain structure 120 would have been (indicated by dashed oval 410) is filled instead with ILD material 109.

FIG. 4E shows a cross-sectional image 450 taken from a semiconductor device manufactured using the illustrative CMGEP approach in which EPI patterning is performed before EPI growth to isolate a transistor, as represented in FIGS. 4A-4D . Such a cross-sectional image 450 can be obtained using various imaging technologies, such as scanning electron microscopy (SEM), transmission electron microscopy (TEM), X-ray computed tomography (XCT), optical microscopy, etc. The cross-sectional image 450 is an X-directional cut through a transistor region of the semiconductor device, similar to the cross-section 400b represented in FIG. 4B. The cross-sectional image 450 shows several structures and layers, such as cross-sections of metal gate lines 130, spacers 452, and linear channel region 140 material, and ILD material 109. Similar to FIG. 4B, the area where the source/drain structure 120 would have been (indicated by dashed oval 410) is filled instead with ILD material 109.

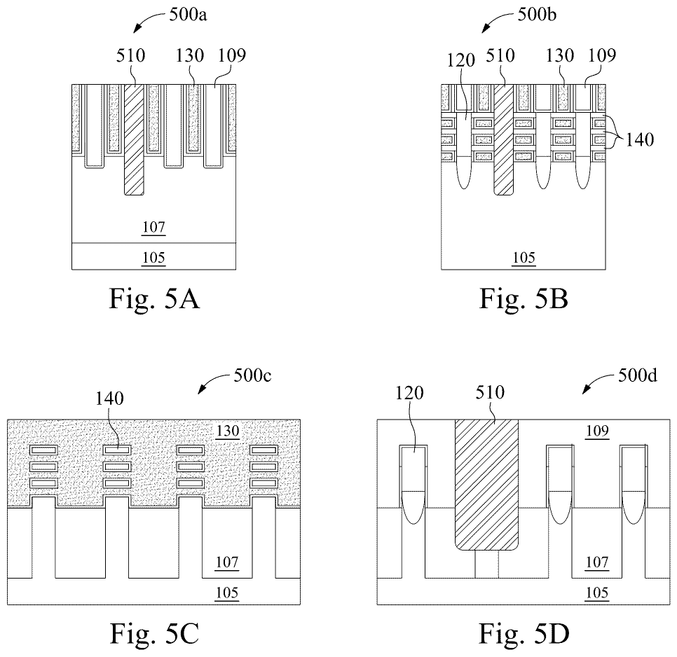

FIGS. 5A-5D represent transistor isolation using an illustrative CMGEP approach in which EPI patterning is performed after EPI growth. In particular, FIGS. 5A-5D represent an illustrative portion of an X-directional cut 500a through a shallow trench isolation (STI) region of a semiconductor device, such as corresponding to cross section ‘A’ of FIG. 1A; an illustrative portion of an X-directional cut 500b through a transistor region of the semiconductor device, such as corresponding to cross section ‘B’ of FIG. 1A; an illustrative portion of a Y-directional cut 500c through a transistor region of the semiconductor device, such as corresponding to cross section ‘C’ of FIG. 1A; and an illustrative portion of a Y-directional cut 500d through an EPI region of the semiconductor device, such as corresponding to cross section ‘D’ of FIG. 1A; respectively. The cross-sectional views 500 show only the EPI patterning, not the CMG.

In general, FIGS. 5A-5D are similar to FIGS. 4A-4D and 1B-1E, and the same reference designators are used where applicable. However, in the illustrated approach of FIGS. 5A-5D, a source/drain structure 120 is etched away after EPI growth, and the removed region is filled. FIGS. 5A, 5B, and 5D illustrate such an approach in which the etched away region (from which a source/drain structure 120 was removed) is filled with a dielectric material 510. “Dielectric material 510” is used herein to refer to any suitable dielectric material for the context in which it is being used. Different references herein to dielectric material 510 can refer to the same or different types of dielectric materials.

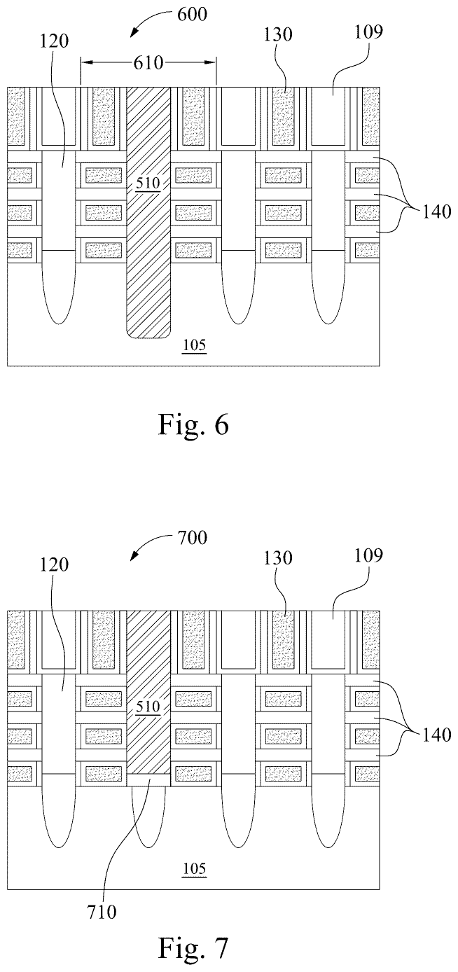

FIG. 6 shows an illustrative portion of an X-directional cut 600 through a transistor region of the semiconductor device after using illustrative CMGEP approaches in which EPI patterning is performed after EPI growth, such as corresponding to that of FIG. 5B. A tolerance range is illustrated by arrow 610. As described further below, there is a relatively large tolerance range over which the etching of the region filled by dielectric material 510 can shift without causing damage to adjacent epitaxial structures. Any damage to the adjacent metal gate lines 130 will not have an effect on adjacent transistors. As such, the tolerance range can be appreciably larger than (e.g., twice that of) the tolerance range for CPODE and CMODE processes.

FIG. 7 shows another illustrative portion of an X-directional cut 700 through a transistor region of the semiconductor device after using illustrative CMGEP approaches in which EPI patterning is performed after EPI growth, similar to that of FIG. 5B. As illustrated, some implementations can include disposing a bottom isolation dielectric 710. In such cases, the etching of the epitaxial structure (post EPI growth) can stop at the top of the bottom isolation dielectric 710.

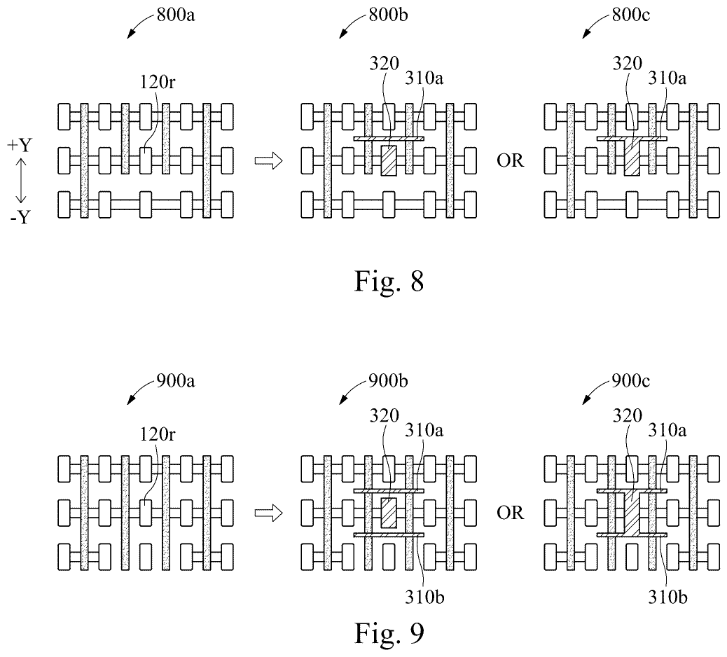

The CMGEP techniques described herein can be implemented in several manners. FIGS. 3A-3C above demonstrate two possible implementations, which can be referred to as I-shaped transistor isolation schemes. FIGS. 8-12 illustrate other example implementations of CMGEP techniques. FIG. 8 shows a first T-shaped CMGEP transistor isolation scheme used to remove one source/drain structure 120 from a semiconductor device, thereby disabling two transistors. As illustrated in view 800a, the metal gate lines 130 adjacent to the to-be-removed source/drain structure 120r extend only in one Y direction (e.g., in the +Y direction, or upward relative to the drawing page) and not in the other Y direction (e.g., not in the −Y direction, or downward relative to the drawing page) beyond the region of the removed source/drain structure 120. For example, this can represent a case in which a poly etching process was used (e.g., CPODE or CMODE) to remove portions of metal gate lines 130 extending in the negative Y direction “below” the removed source/drain structure 120r separate from (although compatible with) the CMGEP techniques described herein. As such, as illustrated in views 800b and 800c, EPI removal 320 is used to remove the source/drain structures 120r, and only one CMG cut 310a is needed to cut the portion of the metal gate lines 130 extending in the positive Y direction “above” the removed source/drain structure 120r. Views 800b and 800c show implementations in which the EPI removal 320 does not and does extend all the way to the location of the CMG cut 310a, respectively.

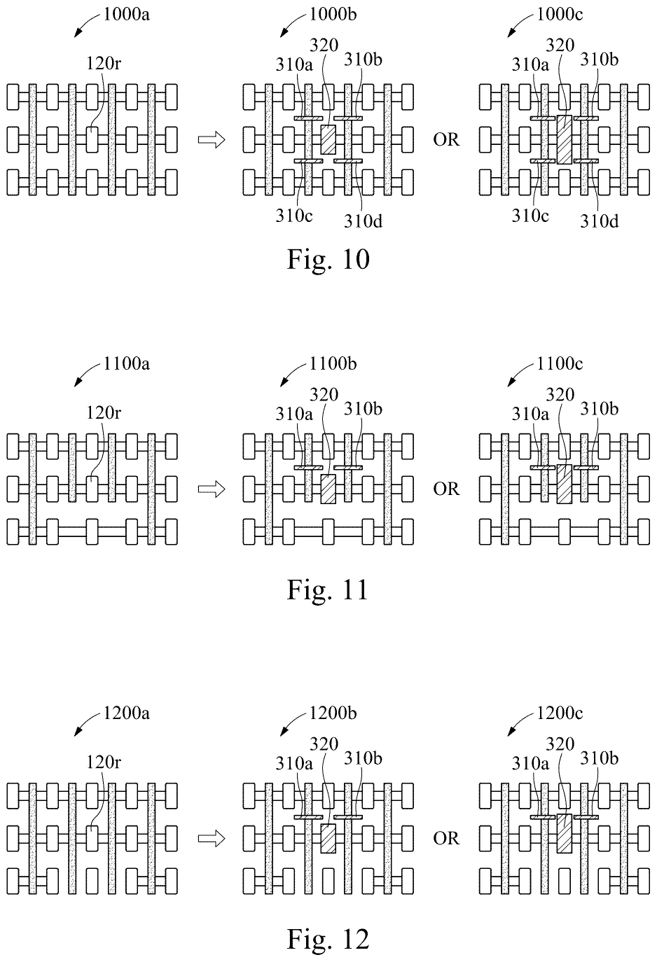

FIG. 9 shows a second I-shaped CMGEP transistor isolation scheme used to remove one source/drain structure 120 from a semiconductor device, thereby disabling two transistors. As illustrated in view 900a, there is no linear channel region 140 directly “below” (relative to the drawing page) the to-be-removed source/drain structure 120r. For example, this can represent a case in which a channel etching process was used to remove portions of channel regions separate from (although compatible with) the CMGEP techniques described herein. As in FIG. 3A-3C, isolating the transistors can involve cutting the metal gate lines 130 both above and below the to-be-removed source/drain structure 120r. As such, as illustrated in views 900b and 900c, EPI removal 320 is used to remove the source/drain structures 120r, and two CMG cuts 310a and 310b are shown to cut the portions of the metal gate lines 130 extending above and below the removed source/drain structure 120r. Views 900b and 900c show implementations in which the EPI removal 320 does not and does extend all the way to the location of the CMG cuts 310, respectively.

FIG. 10 shows a third I-shaped CMGEP transistor isolation scheme used to remove one source/drain structure 120 from a semiconductor device, thereby disabling two transistors. As illustrated in view 1000a, there is a full array of source/drain structures 120, linear channel regions 140, and metal gate lines 130, including a to-be-removed source/drain structure 120r. As in FIGS. 3A-3C , isolating the transistors can involve cutting the metal gate lines 130 both above and below the to-be-removed source/drain structure 120r. Here, separate CMG cuts 310 are used for each portion of each metal gate line 130, resulting in four CMG cuts 310. As illustrated in views 1000b and 1000c, EPI removal 320 is used to remove the source/drain structures 120r, and four CMG cuts 310a-310d are shown to cut the portions of the metal gate lines 130 extending above and below the removed source/drain structure 120r. Views 1000b and 1000c show implementations in which the EPI removal 320 does not and does extend all the way to the location of the CMG cuts 310, respectively.

FIG. 11 shows a second T-shaped CMGEP transistor isolation scheme used to remove one source/drain structure 120 from a semiconductor device, thereby disabling two transistors. As illustrated in view 1100a, the metal gate lines 130 adjacent to the to-be-removed source/drain structure 120r extend only in one Y direction (e.g., in the +Y direction, or upward relative to the drawing page) and not in the other Y direction (e.g., not in the −Y direction, or downward relative to the drawing page) beyond the region of the removed source/drain structure 120. For example, this can represent a case in which a poly etching process was used (e.g., CPODE or CMODE) to remove portions of metal gate lines 130 extending in the negative Y direction “below” the removed source/drain structure 120r separate from (although compatible with) the CMGEP techniques described herein. As such, as illustrated in views 1100b and 1100c, EPI removal 320 is used to remove the source/drain structures 120r, and CMG cuts 310 are needed to cut the portion of the metal gate lines 130 extending only in the positive Y direction “above” the removed source/drain structure 120r. As in FIG. 10, separate CMG cuts 310 are used for each portion of each metal gate line 130, resulting in two CMG cuts 310a and 310b. Views 1100b and 1100c show implementations in which the EPI removal 320 does not and does extend all the way to the location of the CMG cuts 310, respectively.

FIG. 12 shows a fourth I-shaped CMGEP transistor isolation scheme used to remove one source/drain structure 120 from a semiconductor device, thereby disabling two transistors. As illustrated in view 1200a, there is no linear channel region 140 directly “below” (relative to the drawing page) the to-be-removed source/drain structure 120r. For example, this can represent a case in which a channel etching process was used to remove portions of channel regions separate from (although compatible with) the CMGEP techniques described herein. As in FIGS. 3A-3C , isolating the transistors can involve cutting the metal gate lines 130 both above and below the to-be-removed source/drain structure 120r. As such, as illustrated in views 1200b and 1200c, EPI removal 320 is used to remove the source/drain structures 120r, and two CMG cuts 310a and 310b are shown to cut the portions of the metal gate lines 130 extending above and below the removed source/drain structure 120r. Views 1200b and 1200c show implementations in which the EPI removal 320 does not and does extend all the way to the location of the CMG cuts 310, respectively.

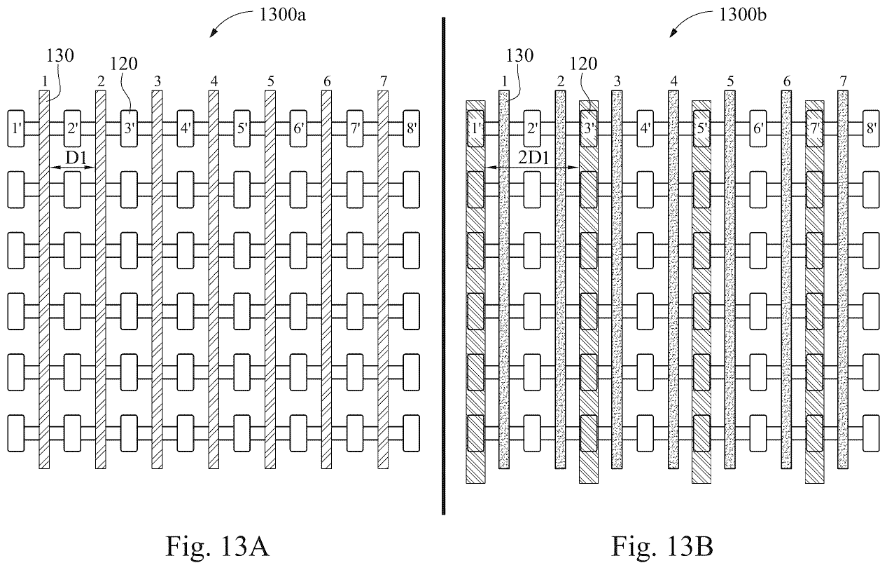

FIGS. 13A and 13B show a comparison of pitch size between CPODE-type and EPI patterning-based transistor isolation approaches. Each of FIGS. 13A and 13B shows an example portion (i.e., the example portion 1300a and the example portion 1300b) of a semiconductor device 1300 having an array of transistors 110 made up of an array of source/drain structures 120 disposed on linear channel regions 140 activated by metal gate lines 130 running perpendicularly to the channel regions 140. FIG. 13A demonstrates an example of transistor isolation by CPODE, CMODE, or other processes involving removal of metal gate lines 130. Such an approach results in a pitch size (D) based on the X-wise distance from each metal gate line 130 to its adjacent metal gate lines 130. FIG. 13B demonstrates an example of transistor isolation by CMGEP techniques described herein. Such an approach results in an appreciably larger pitch size (e.g., 2D) based on the X-wise distance from each source/drain structure 120 to its adjacent source/drain structures 120. As described above, such an increase in pitch size can appreciably reduce the danger of scum defects, PR peeling defects, and/or other defects as structure sizes continue to decrease and/or transistor densities continue to increase.

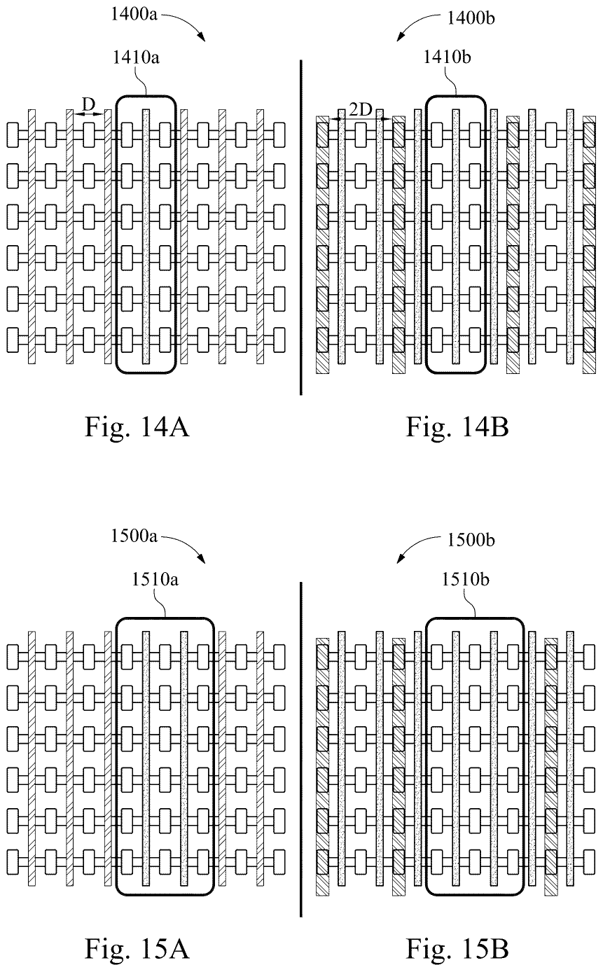

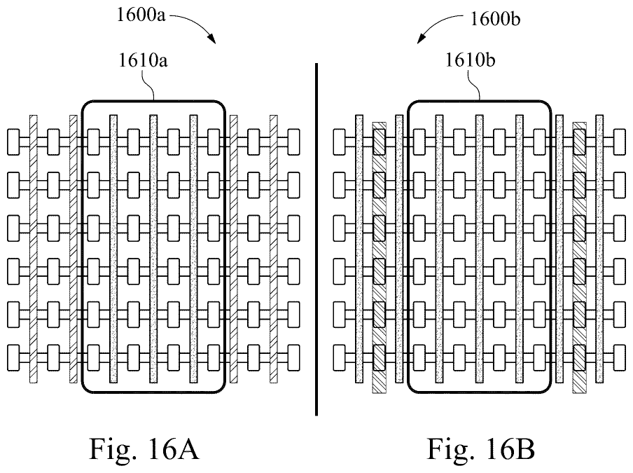

FIGS. 14A and 14B show top-down views 1400 of a comparison between CPODE-type and EPI patterning-based transistor isolation approaches, respectively, for enabling a single active line 1410 of transistors. FIGS. 15A and 15B show top-down views 1500 of a comparison between CPODE-type and EPI patterning-based transistor isolation approaches, respectively, for enabling two active lines 1510 of transistors. FIGS. 16A and 16B show top-down views 1600 of a comparison between CPODE-type and EPI patterning-based transistor isolation approaches, respectively, for enabling three active lines 1610 of transistors. As in FIGS. 13A and 13B, each of FIGS. 14A and 14B, FIGS. 15A and 15B, and FIGS. 16A and 16B shows a same example portion of a semiconductor device having an array of transistors 110 made up of an array of source/drain structures 120 disposed on linear channel regions 140 activated by metal gate lines 130 running perpendicularly to the channel regions 140.

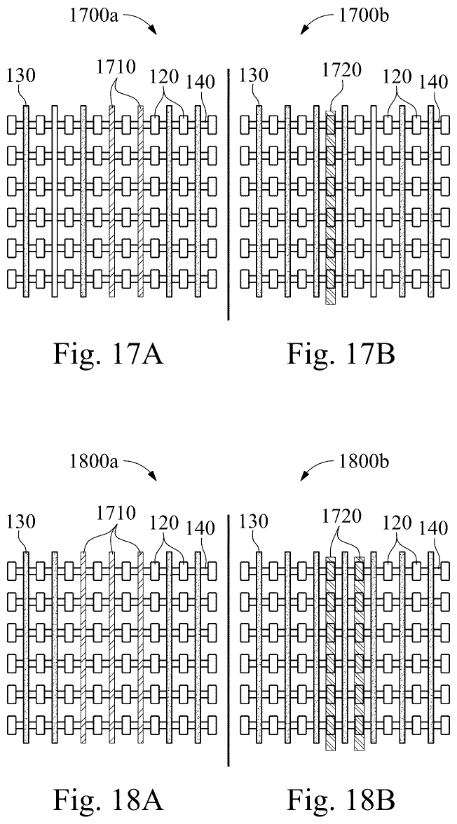

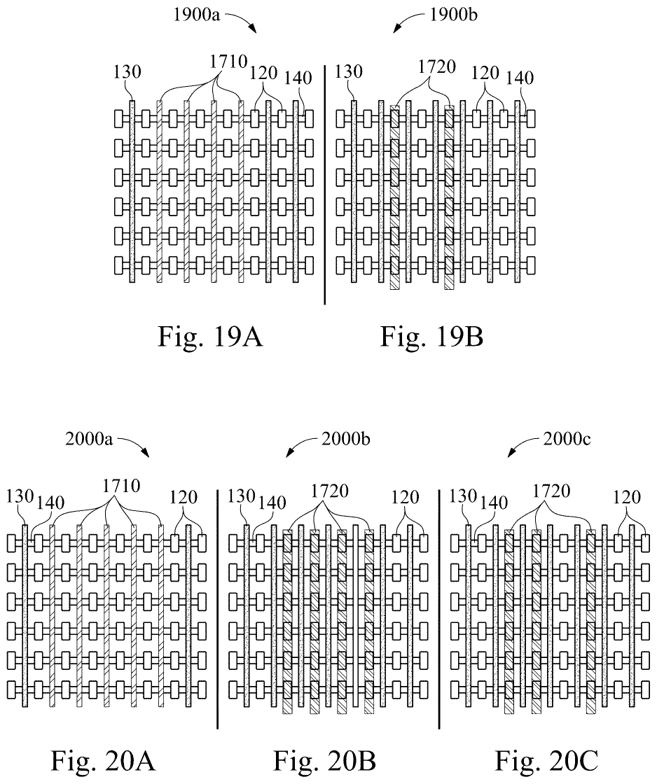

As in FIGS. 13A and 13B, each of FIGS. 17A and 17B, FIGS. 18A and 18B, and FIGS. 19A and 19B, and 20A-20C shows a same example portion of a semiconductor device having an array of transistors 110 made up of an array of source/drain structures 120 disposed on linear channel regions 140 activated by metal gate lines 130 running perpendicularly to the channel regions 140. FIGS. 17A and 17B show top-down views 1700 of a comparison between CPODE-type and EPI patterning-based transistor isolation approaches, respectively, for disabling two columns of transistors. The CPODE-type approach leaves two disabled gate lines 1710, and the EPI patterning-based transistor isolation approach leaves a disabled column of epitaxial structures 1720. FIGS. 18A and 18B show top-down views 1800 of a comparison between CPODE-type and EPI patterning-based transistor isolation approaches, respectively, for disabling three columns of transistors. The CPODE-type approach leaves three disabled gate lines 1710, and the EPI patterning-based transistor isolation approach leaves two disabled columns of epitaxial structures 1720. FIGS. 19A and 19B show top-down views 1900 of a comparison between CPODE-type and EPI patterning-based transistor isolation approaches, respectively, for disabling four columns of transistors. The CPODE-type approach leaves four disabled gate lines 1710, and the EPI patterning-based transistor isolation approach again leaves two disabled columns of epitaxial structures 1720. FIGS. 20A-20C show top-down views 2000 of a comparison between CPODE-type and two different EPI patterning-based transistor isolation approaches, respectively, for disabling five columns of transistors. The CPODE-type approach leaves five disabled gate lines 1710, and the EPI patterning-based transistor isolation approaches leave either four or three disabled columns of epitaxial structures 1720.

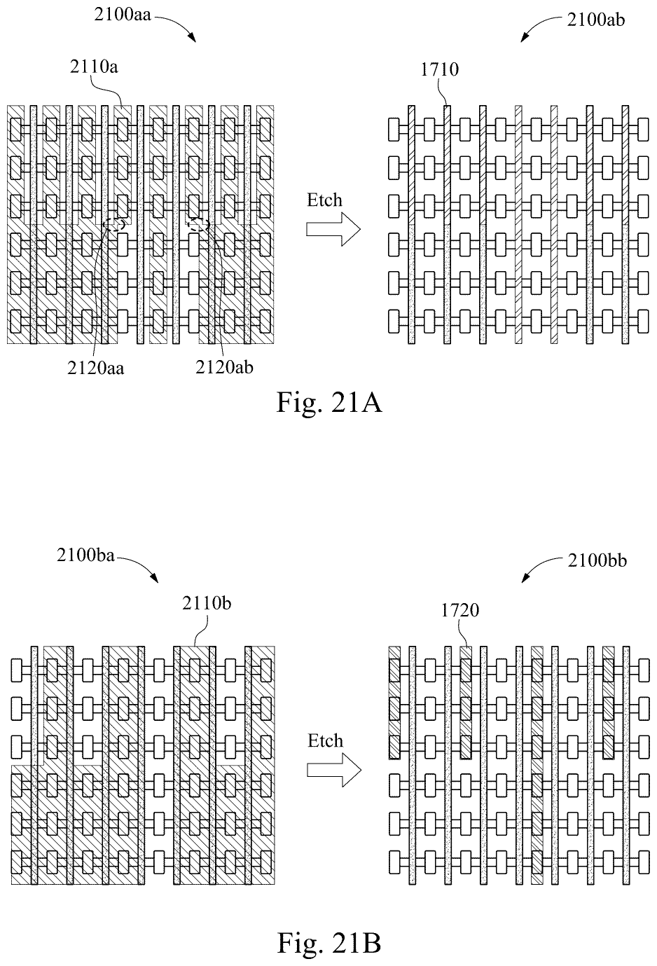

FIGS. 21A and 21B show top-down views 2100 of a comparison between CPODE-type and EPI patterning-based transistor isolation approaches, respectively, for disabling two columns of transistors in an estuary. In FIG. 21A, view 2100aa shows regions not to be etched as covered by a patterned photoresist layer 2110a, and view 2100ab shows the resulting etched pattern (i.e., with metal gate lines 130 etched according to a CPODE, CMODE, or other similar etching approach, leaving disabled gate lines 1710). View 2100aa shows transition regions 2120aa and 2120ab at the upper boundary (relative to the drawing page) of the estuary. Defining the estuary results in each of the boundary regions 2120 having a very thin section of photoresist. As described above, such thin sections of photoresist can result in PR peeling and/or other undesirable artifacts. In FIG. 21B, view 2100ba shows regions not to be etched as covered by a patterned photoresist layer 2110b, and view 2100bb shows the resulting etched pattern (i.e., with source/drain structures 120 etched according to a CMGEP approach, leaving disabled columns of epitaxial structures 1720). Unlike in FIG. 21A, defining the estuary in FIG. 21B does not leave transition regions with very thin sections of photoresist and can avoid PR peeling and/or other undesirable artifacts.

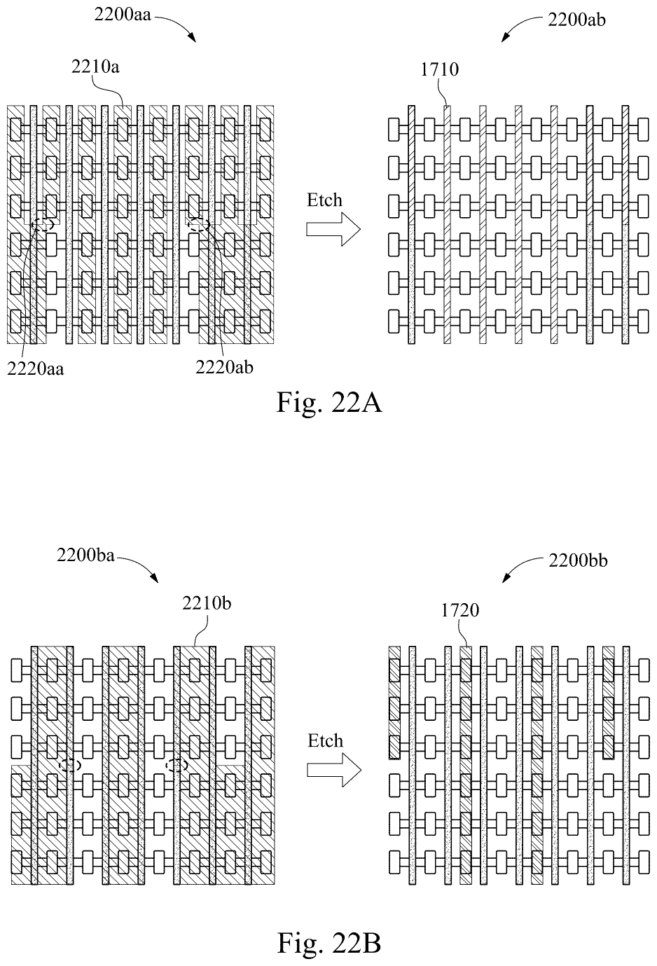

FIGS. 22A and 22B show top-down views 2200 of a comparison between CPODE-type and EPI patterning-based transistor isolation approaches, respectively, for disabling four columns of transistors in an estuary. In FIG. 22A, view 2200aa shows regions not to be etched as covered by a patterned photoresist layer 2210a, and view 2200ab shows the resulting etched pattern (i.e., with metal gate lines 130 etched according to a CPODE, CMODE, or other similar etching approach, leaving disabled gate lines 1710). View 2200aa shows transition regions 2220aa and 2220ab at the upper boundary (relative to the drawing page) of the estuary. Defining the estuary results in each of the boundary regions 2220 having a very thin section of photoresist. As described above, such thin sections of photoresist can result in PR peeling and/or other undesirable artifacts. In FIG. 22B, view 2200ba shows regions not to be etched as covered by a patterned photoresist layer 2210b, and view 2200bb shows the resulting etched pattern (i.e., with source/drain structures 120 etched according to a CMGEP approach, leaving disabled columns of epitaxial structures 1720). Unlike in FIG. 22A, defining the estuary in FIG. 22B does not leave transition regions with very thin sections of photoresist and can avoid PR peeling and/or other undesirable artifacts.

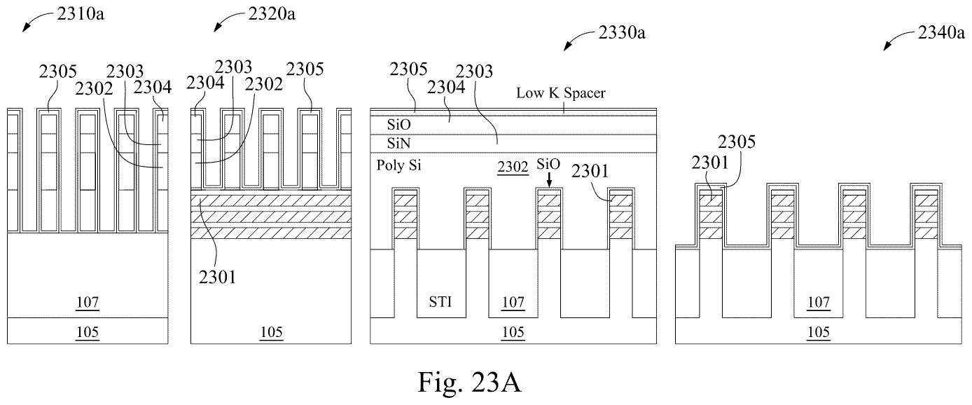

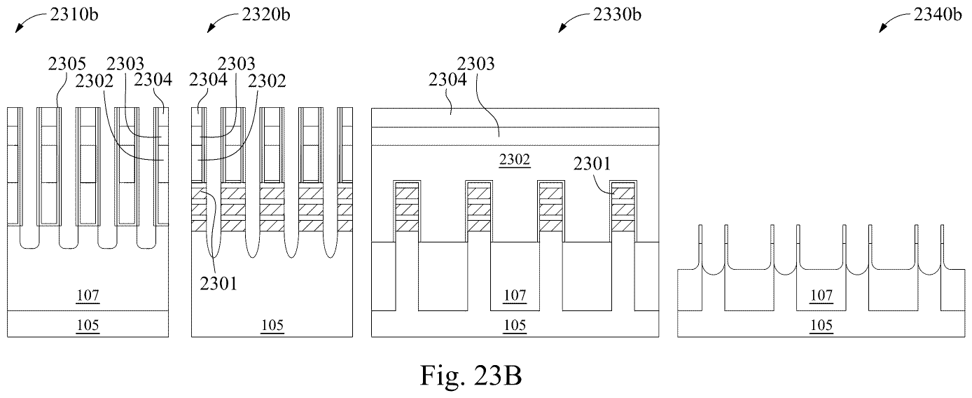

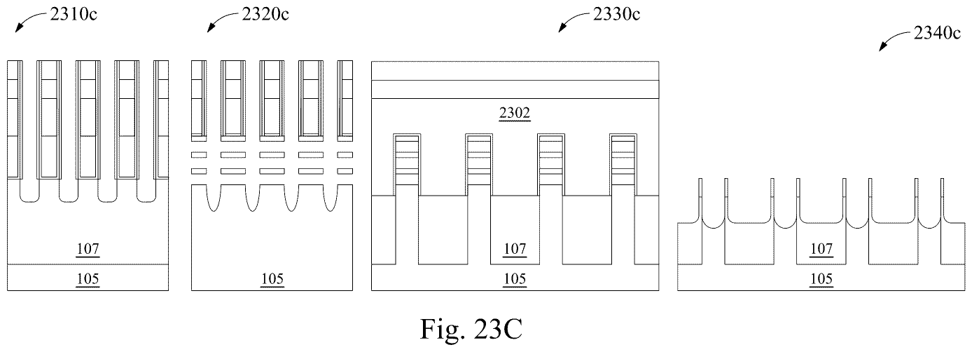

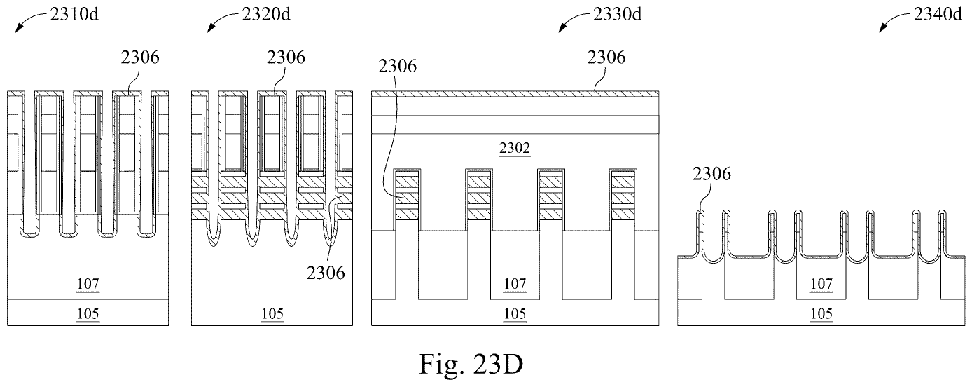

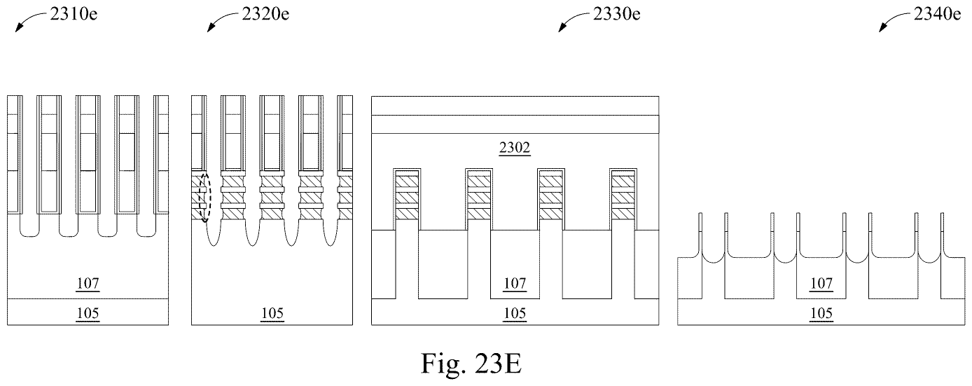

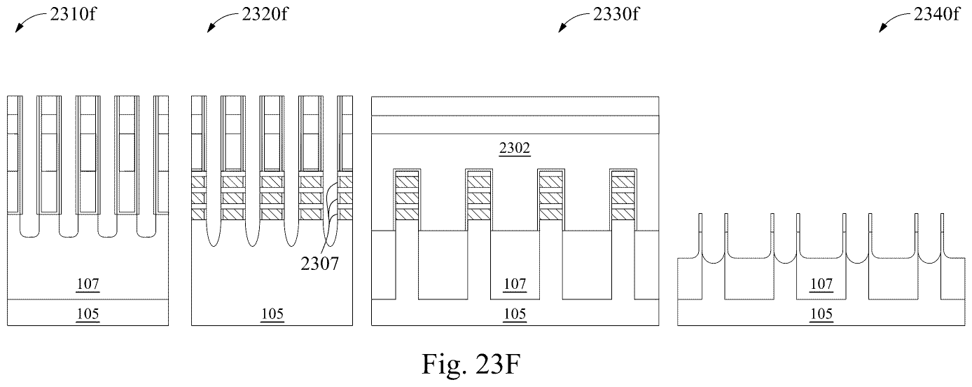

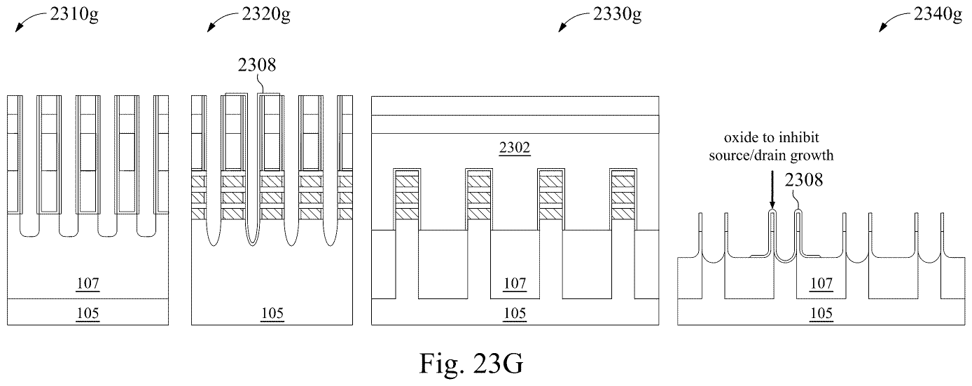

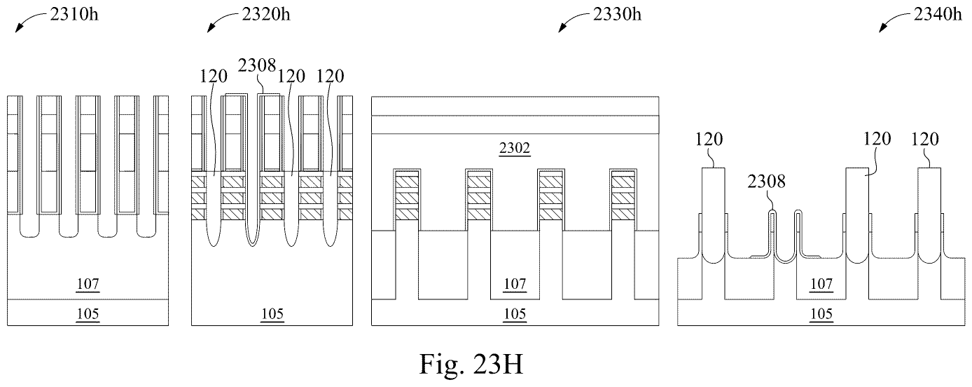

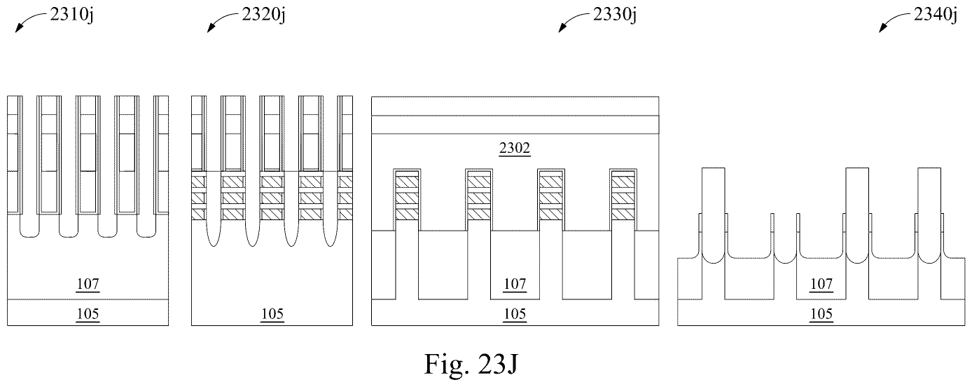

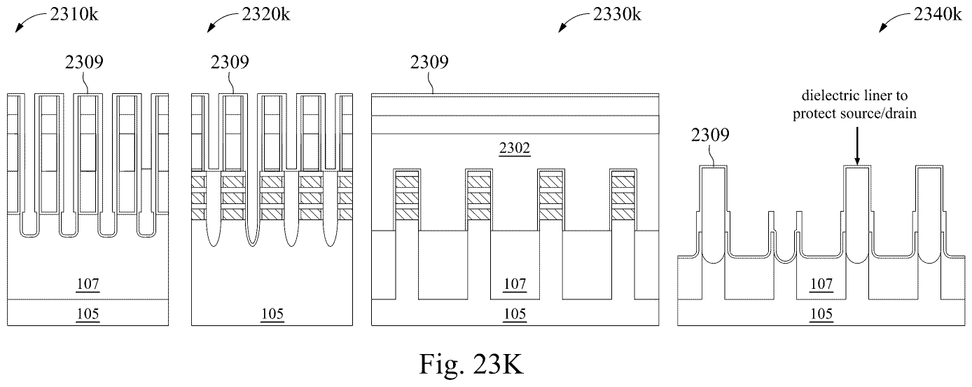

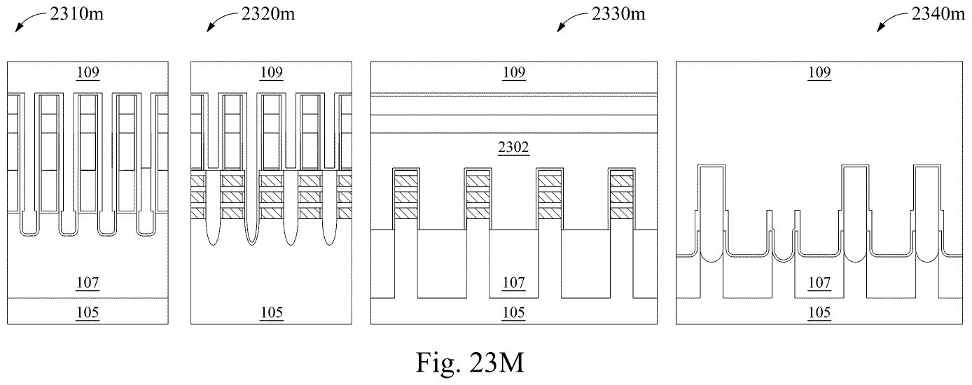

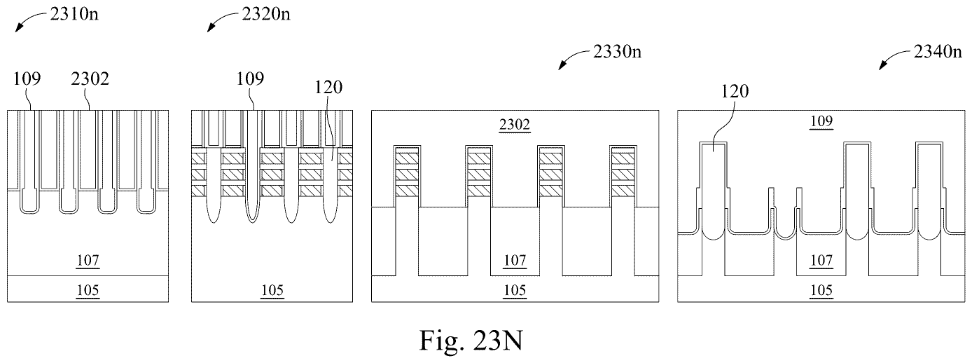

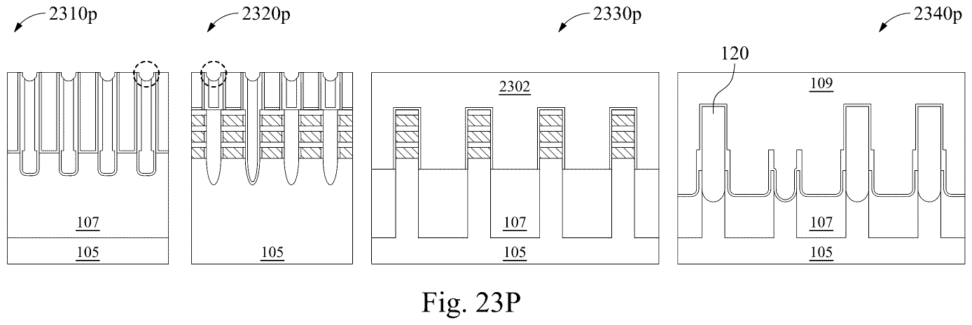

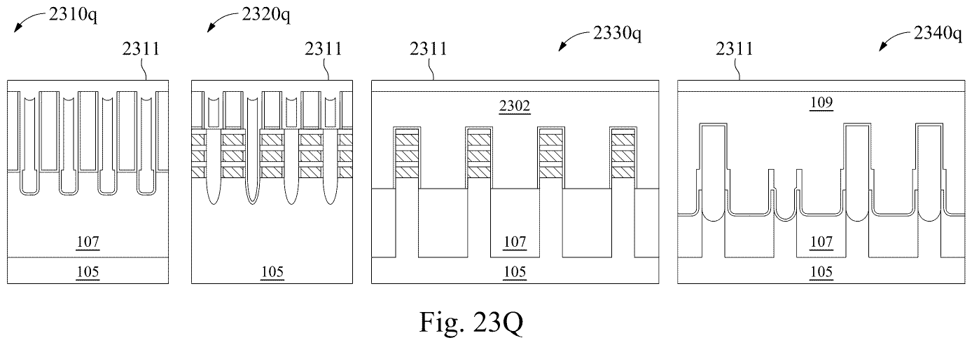

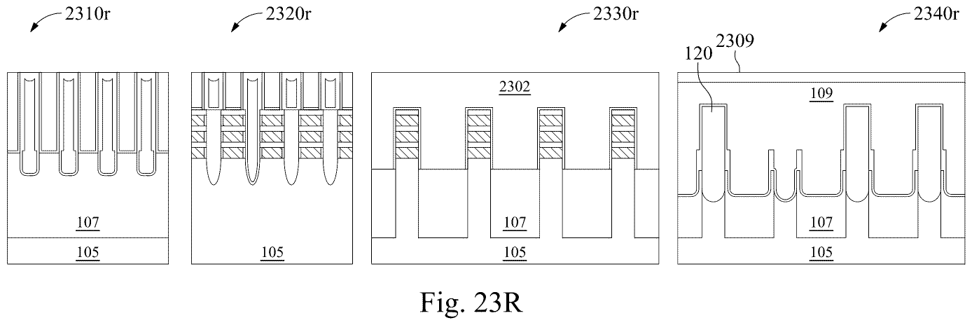

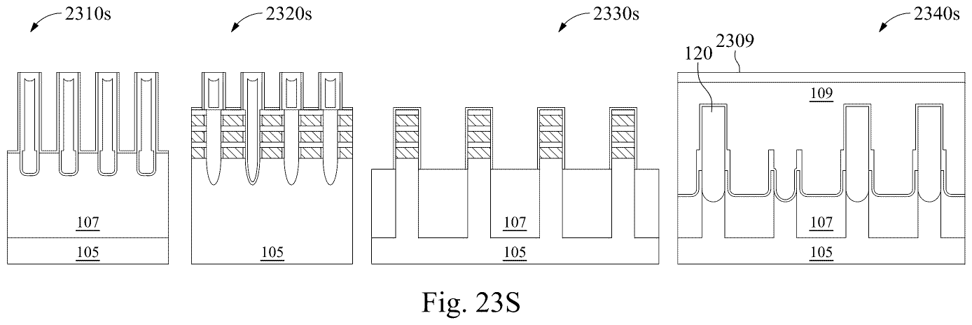

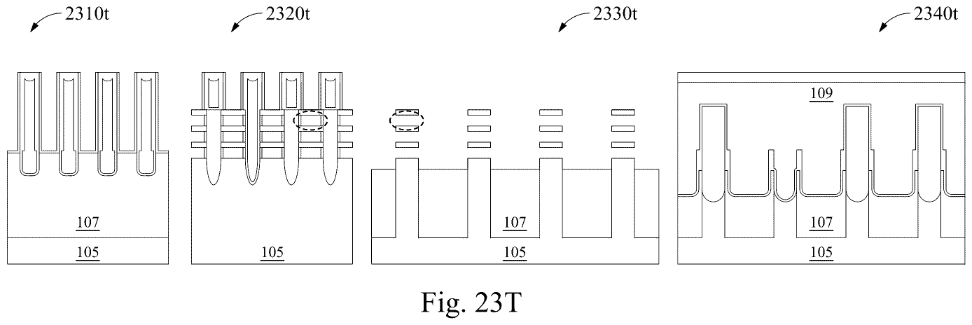

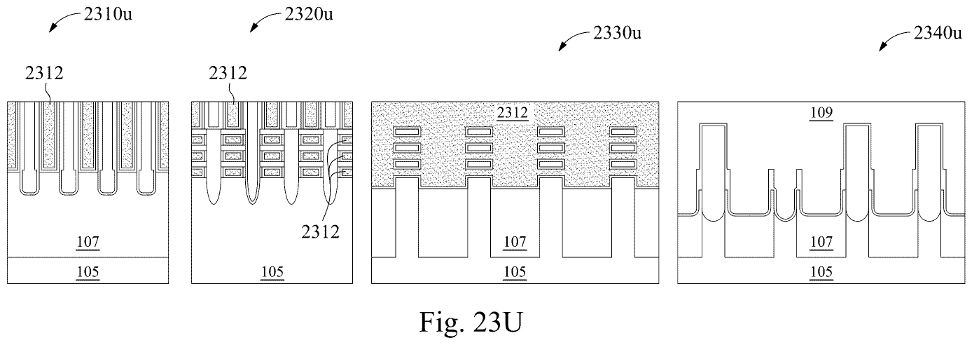

FIGS. 23A-23U illustrate a sequence of stages of a nanosheet transistor fabrication process including EPI patterning before EPI growth, according to some embodiments described herein. Each stage is shown in four views: an illustrative portion of an X-directional cut 2310 through a shallow trench isolation (STI) region of a semiconductor device, such as corresponding to cross section ‘A’ of FIG. 1A; an illustrative portion of an X-directional cut 2320 through a transistor region of the semiconductor device, such as corresponding to cross section ‘B’ of FIG. 1A; an illustrative portion of a Y-directional cut 2330 through a transistor region of the semiconductor device, such as corresponding to cross section ‘C’ of FIG. 1A; and an illustrative portion of a Y-directional cut 2340 through an EPI region of the semiconductor device, such as corresponding to cross section ‘D’ of FIG. 1A; respectively. For example, a first stage is represented by FIG. 23A and includes cross-sectional views 2310a, 2320a, 2330a, and 2340a. The stages represented by FIGS. 23A-23U are not intended to show every stage; rather the focus is on stages relevant to epitaxial growth of source/drain structures 120. For example, the illustrated stages do not include preprocessing stages and certain intermediary stages.

FIG. 23A illustrates a spacer deposition stage. The different cross-sectional views show several illustrative layers, including a substrate 105, an STI layer 107, one or more silicon germanium interposer layers 2301, a polysilicon (dummy gate) layer 2302, a silicon nitride layer 2303, a silicon oxide layer 2304, and a spacer layer 2305. The spacer layer 2305 is a low-K dielectric. The stage involves depositing a thin layer of insulating material (e.g., silicon nitride or silicon dioxide) onto the sidewalls of the fin structure to create the spacer layer 2305. This can create a spacer to define the gate length and to isolate the gate (metal gate lines 130) from the source and drain regions (source/drain structures 120), for example to provide electrical insulation.

FIG. 23B illustrates a source and drain etch stage in which regions are patterned and etched for subsequent growth of source/drain structures 120. FIG. 23C illustrates an interposer removal stage in which the silicon germanium (SiGe) interposer layers 2301 are removed. For example, the SiGe interposer layers 2301 are used to create precise structural profiles and are now removed. FIG. 23D illustrates an interposer deposition stage in which oxide interposer layers 2306 are deposited. For example, the new oxide (e.g., silicon dioxide) interposer layers 2306 can provide new mechanical support with electrical isolation (although the oxide interposer layers 2306 are removed prior to metal gate formation in this process).

FIG. 23E illustrates an interposer recess process to form recesses in the oxide interposer regions (one indicated by a dashed oval region). In FIG. 23F, interspacer material 2307 is deposited in the recesses formed in FIG. 23E. The interspacer material 2307 can be a low-K dielectric nitride or other suitable insulator material for providing insulation for subsequently grown source/drain structures 120. The interspacer material 2307 is not made of pure silicon to avoid removing the interspacer material 2307 when the oxide interposer layers 2306 are removed in a later stage. Also, the interspacer material 2307 is not pure silicon carbide or pure silicon nitride because the dielectric constant would be too high (resulting in a very large parasitic capacitance).

FIG. 23G illustrates a lithography patterning and etch stage. Although a particular set of layers is illustrated, the lithography can involve a two-layer, three-layer, tetralayer, or other process. In this stage a growth inhibiting layer 2308 is deposited to prevent epitaxial growth in the corresponding region in the subsequent stage. The growth inhibiting layer 2308 can be aluminum oxide, or other material having a very large lattice mismatch with the material to be grown epitaxially. FIG. 23H illustrates an epitaxial growth stage for growing source/drain structures 120 in the regions not coated by a growth inhibiting layer 2308. Views 2320h and 2340h show epitaxially grown source/drain structures 120 in all previously etched regions except the one coated with the growth inhibiting layer 2308. For example, in a PNP transistor structure, a source/drain structure 120 may be grown with silicon-germanium or silicon-boron material, both having a very similar lattice structure to the silicon material exposed in the etched regions (e.g., between and below the oxide interposer layers 2306).

In FIG. 23J, the growth inhibiting layer 2308 is removed, such as by wet etching. In FIG. 23K, a capping etch layer (CEL) material 2309 is deposited. The CEL material 2309 acts as a hard mask or a protective layer to stop or control etching in certain regions of the wafer, so that specific areas are protected from etching during subsequent etching stages. FIG. 23M illustrates an ILD deposition stage in which a layer of ILD material 109 is deposited. FIG. 23N illustrates a CMP (“Chemical Mechanical Planarization” or “Chemical Mechanical Polishing”) stage in which CMP techniques are used to smooth and planarize the surface of the wafer.

In FIG. 23P, recesses are formed in the ILD material 109 layer at the source/drain structure 120 locations (some indicated by dashed regions). In FIG. 23Q, an ILD capping layer 2311 (e.g., silicon nitride) is deposited over the ILD material 109, including in the recesses. FIG. 23R illustrates another CMP stage to again smooth and planarize the surface of the wafer. In FIG. 23S, the dummy gate layer 2302 is removed. FIG. 23T illustrates an oxide interposer removal stage in which the oxide interposer layers 2306 are removed (some indicated by dashed regions). Notably, the ILD material 109 is also oxide, but the ILD material 109 is protected from removal in this stage by the ILD capping layer 2311 deposited in the preceding stage. In FIG. 23U, a metal gate layer 2312 (i.e., the real gate layer) is deposited in place of the dummy gate layer 2303, and CMP can be performed again.

As noted herein, embodiments involve selectively disabling source/drain structures 120 (“EPI disable” techniques) combined with cut metal gate (CMG) techniques to selectively disable transistors in a large array of nanosheet transistors. FIGS. 23A-23U illustrate one approach to disabling source/drain structures 120 by effectively preventing epitaxial growth of those structures in selected locations. Another approach is to selectively remove epitaxially grown source/drain structures 120 (i.e., subsequent to epitaxial growth) by etching. In some embodiments, such removal is performed prior to metal gate deposition. In other embodiments, such removal is performed subsequent to metal gate deposition.

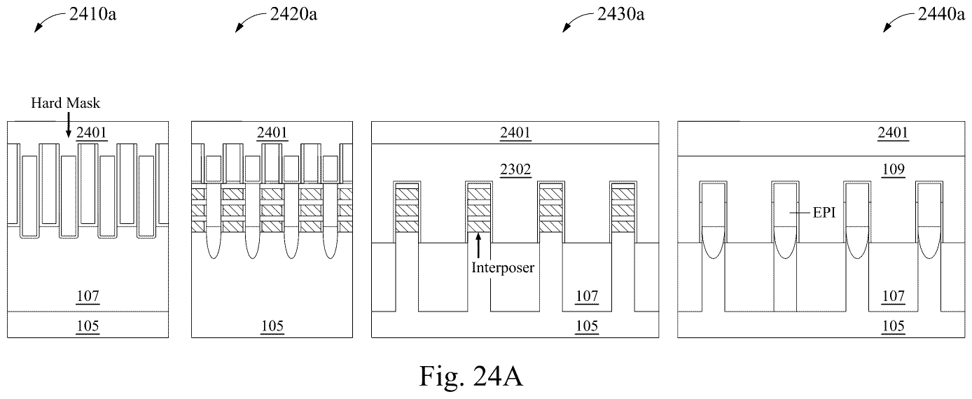

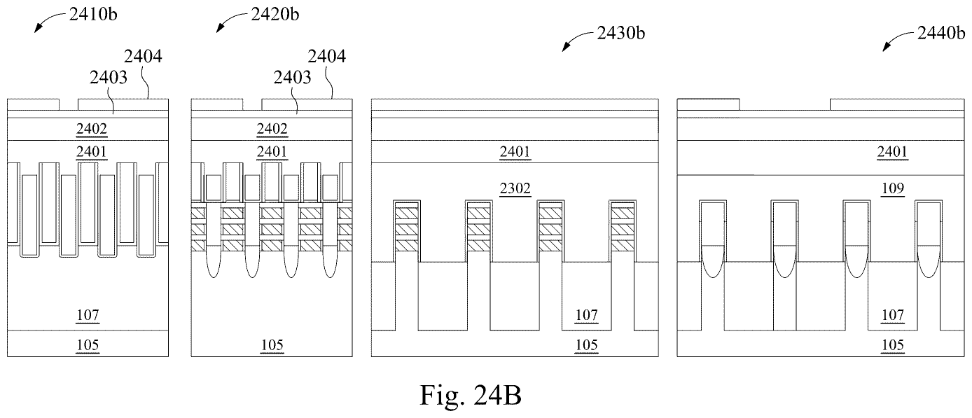

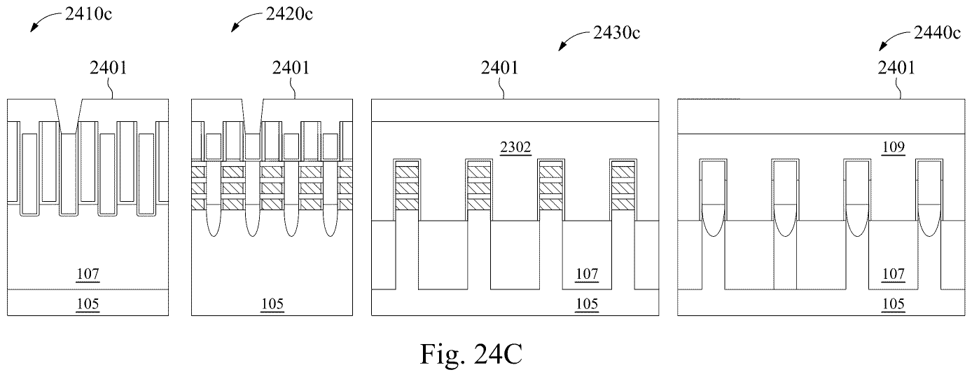

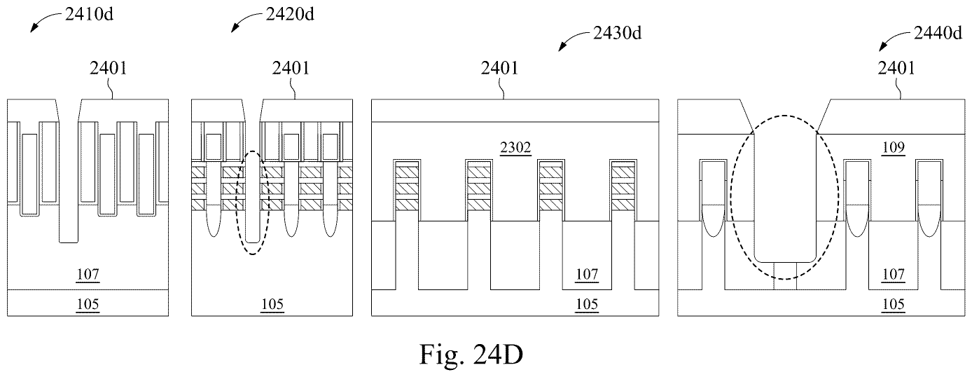

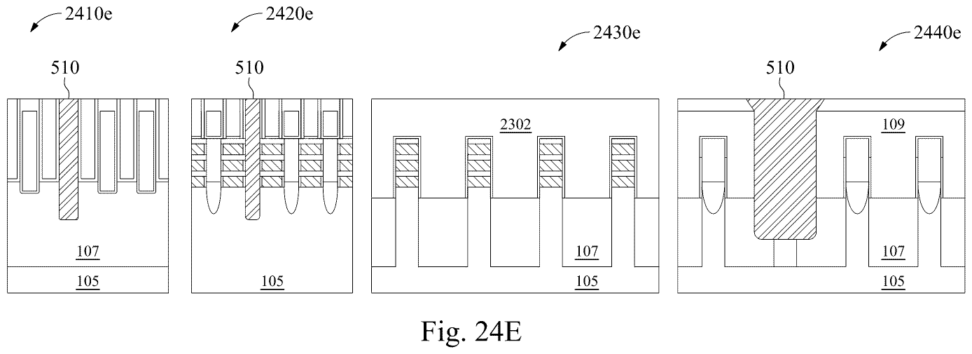

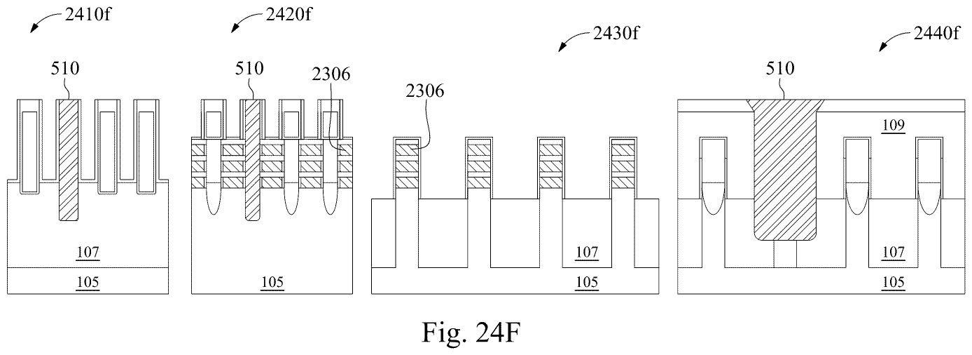

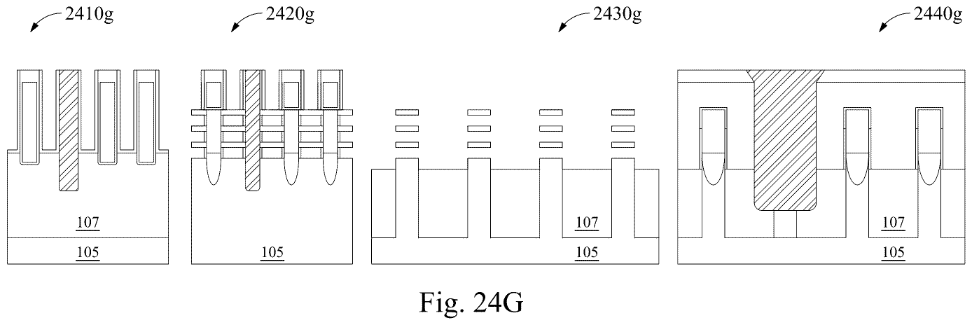

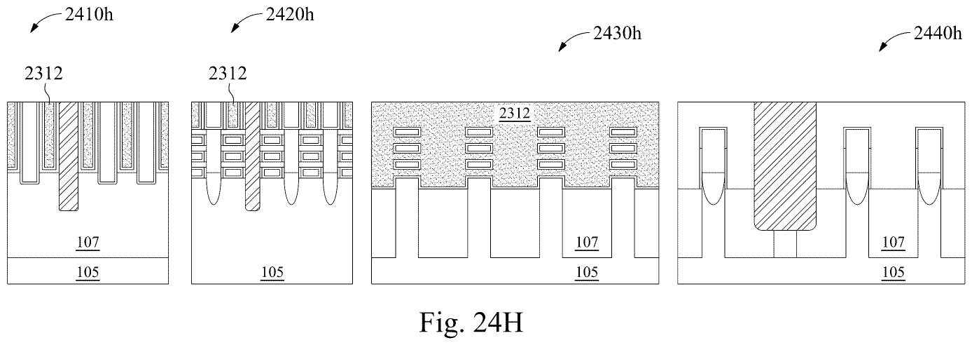

FIGS. 24A-24H illustrate a sequence of stages of a nanosheet transistor fabrication process including selectively removing epitaxially grown source/drain structures 120 prior to metal gate deposition (during front end of line, FEOL), according to some embodiments described herein. Each stage is shown in four views: an illustrative portion of an X-directional cut 2410 through a shallow trench isolation (STI) region of a semiconductor device, such as corresponding to cross section ‘A’ of FIG. 1A; an illustrative portion of an X-directional cut 2420 through a transistor region of the semiconductor device, such as corresponding to cross section ‘B’ of FIG. 1A; an illustrative portion of a Y-directional cut 2430 through a transistor region of the semiconductor device, such as corresponding to cross section ‘C’ of FIG. 1A; and an illustrative portion of a Y-directional cut 2440 through an EPI region of the semiconductor device, such as corresponding to cross section ‘D’ of FIG. 1A, respectively. For example, a first stage is represented by FIG. 24A and includes cross-sectional views 2410a, 2420a, 2430a, and 2440a. The stages represented by FIGS. 24A-24H are not intended to show every stage.

FIG. 24A illustrates a hard mask deposition stage in which a hard mask layer 2401 is deposited over the surface of the wafer. FIG. 24B illustrates a lithography patterning stage. Although a particular set of layers is illustrated, the lithography can involve a two-layer, three-layer, tetralayer, or other process. As illustrated, a bottom layer 2402, a middle layer 2403, and a photoresist layer 2404 are deposited, and the photoresist layer 2404 is patterned to facilitate etching in the location of the source/drain structure 120 to be removed. FIG. 24C illustrates a first etching stage to form an opening through the hard mask layer 2401 in the desired location corresponding to the source/drain structure 120 to be removed. FIG. 24D illustrates a second etching stage for effectively removing the selected, previously grown source/drain structure 120 (indicated by a dashed region). In FIG. 24E, a dielectric material 510 is deposited in the etched region and CMP is used to planarize the surface.

FIGS. 24F-24H can correspond to the stages of FIGS. 23S-23U , respectively. In FIG. 24F, dummy gate layer 2302 is removed. FIG. 24G illustrates an oxide interposer removal stage in which the oxide interposer layers 2306 are removed. In FIG. 24H, metal gate layer 2312 is deposited in place of the dummy gate layer 2302, and CMP can be performed again.

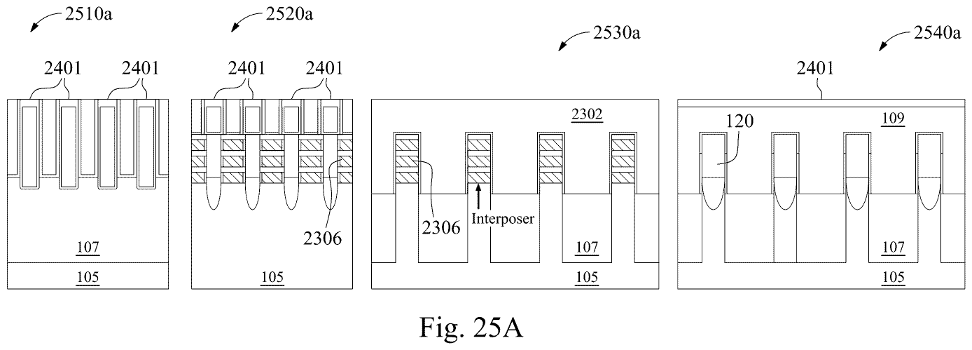

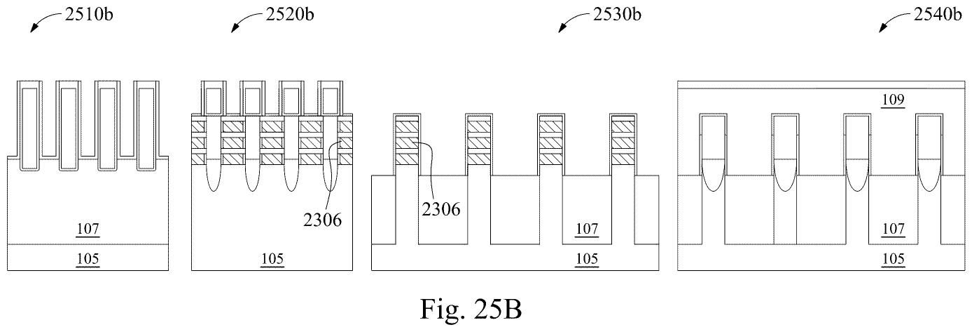

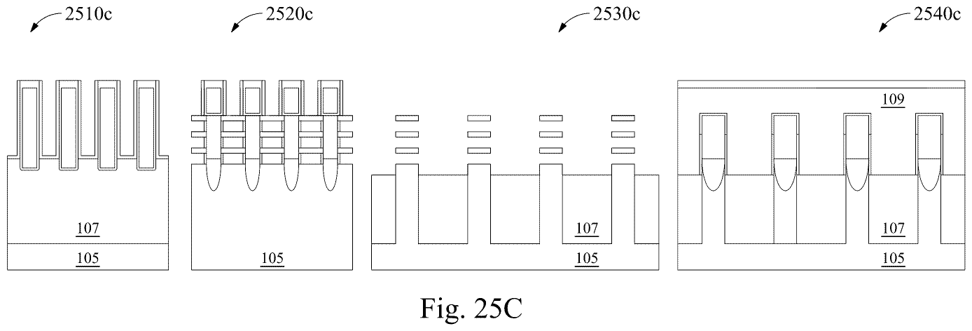

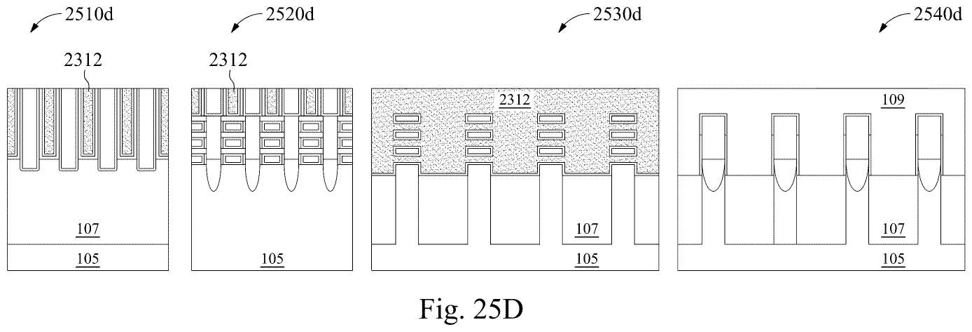

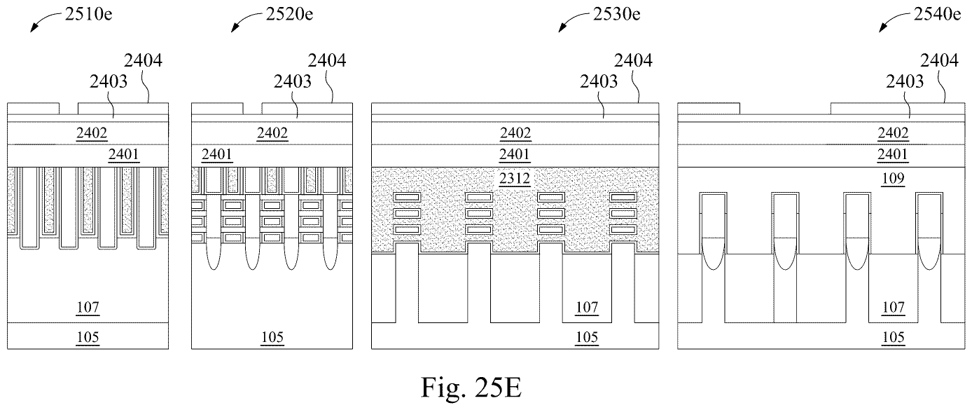

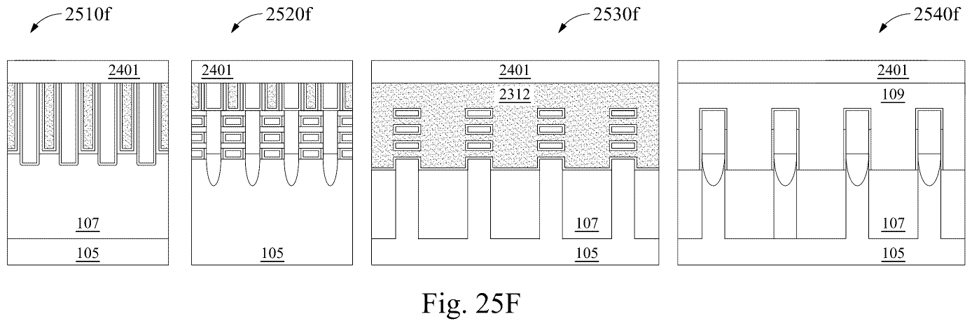

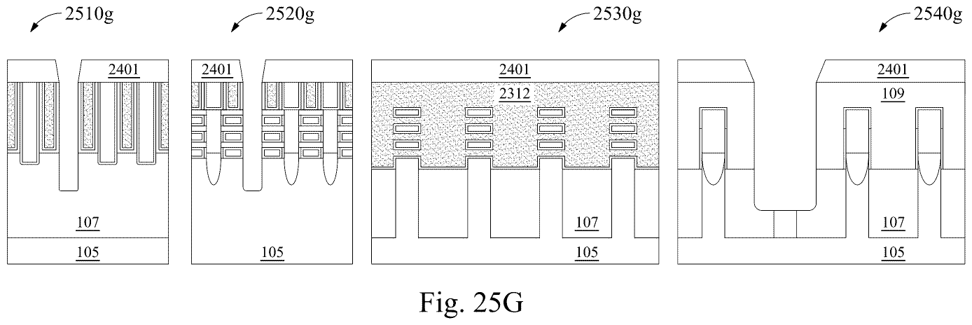

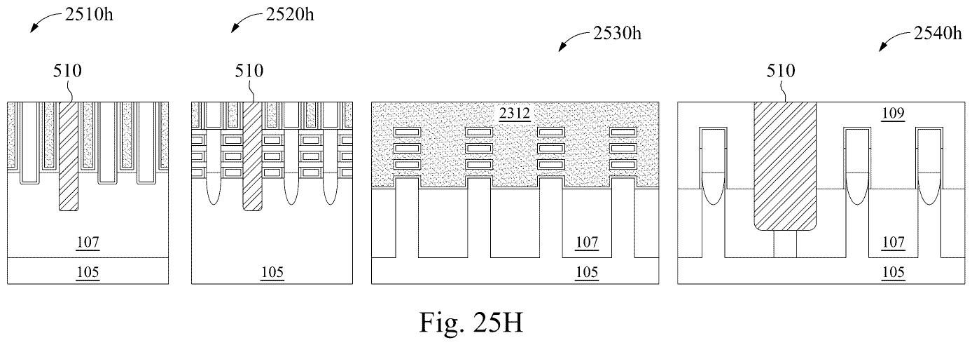

FIGS. 25A-25H illustrate a sequence of stages of a nanosheet transistor fabrication process including selectively removing epitaxially grown source/drain structures 120 subsequent to metal gate deposition (during middle end of line, MEOL), according to some embodiments described herein. Each stage is shown in four views: an illustrative portion of an X-directional cut 2510 through a shallow trench isolation (STI) region of a semiconductor device, such as corresponding to cross section ‘A’ of FIG. 1A; an illustrative portion of an X-directional cut 2520 through a transistor region of the semiconductor device, such as corresponding to cross section ‘B’ of FIG. 1A; an illustrative portion of a Y-directional cut 2530 through a transistor region of the semiconductor device, such as corresponding to cross section ‘C’ of FIG. 1A; and an illustrative portion of a Y-directional cut 2540 through an EPI region of the semiconductor device, such as corresponding to cross section ‘D’ of FIG. 1A; respectively. For example, a first stage is represented by FIG. 25A and includes cross-sectional views 2510a, 2520a, 2530a, and 2540a. The stages represented by FIGS. 25A-25H are not intended to show every stage.

FIG. 25A illustrates a CMP stage after deposition of a hard mask 2401 and in preparation for removal of a dummy gate layer 2302. In FIG. 25B, the dummy gate layer 2302 is removed (e.g., as in FIGS. 23S and 24F). FIG. 25C illustrates an oxide interposer removal stage in which the oxide interposer layers 2306 are removed (e.g., as in FIGS. 23T and 24G). In FIG. 25D, metal gate layer 2312 is deposited in place of the dummy gate layer 2302, and CMP can be performed again (e.g., as in FIGS. 23U and 24H).

FIG. 25E illustrates a lithography patterning stage. A preceding stage is assumed in which a hard mask layer is deposited over the surface of the wafer. Although a particular set of layers is illustrated, the lithography can involve a two-layer, three-layer, tetralayer, or other process. As illustrated, a bottom layer 2402, a middle layer 2403, and a photoresist layer 2404 are deposited, and the photoresist layer 2404 is patterned to facilitate etching in the location of the source/drain structure 120 to be removed. FIG. 25F illustrates a first etching stage to form an opening through the hard mask layer 2401 in the desired location corresponding to the source/drain structure 120 to be removed. FIG. 25G illustrates a second etching stage for effectively removing the selected, previously grown source/drain structure 120. In FIG. 25H, a dielectric material 510 is deposited in the etched region and CMP is used to planarize the surface. It can be seen that the stages of FIGS. 25E-25H are similar to those of FIG. 24B 24E, respectively, except that they are performed subsequent to depositing the metal gate layer 2312.

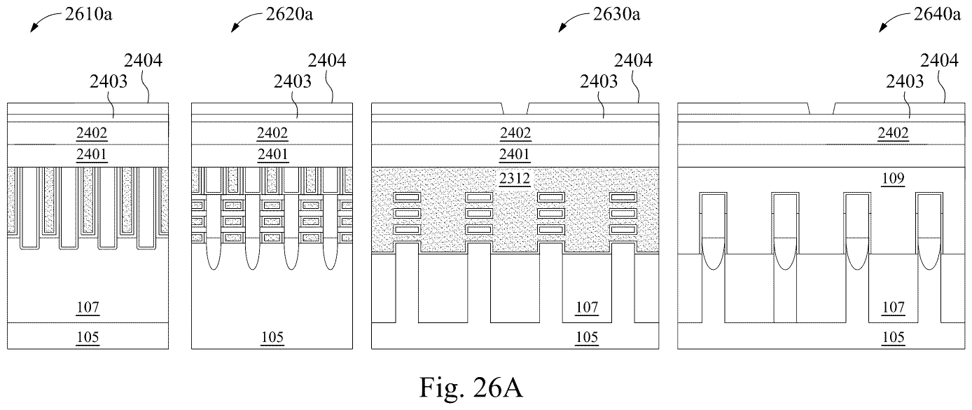

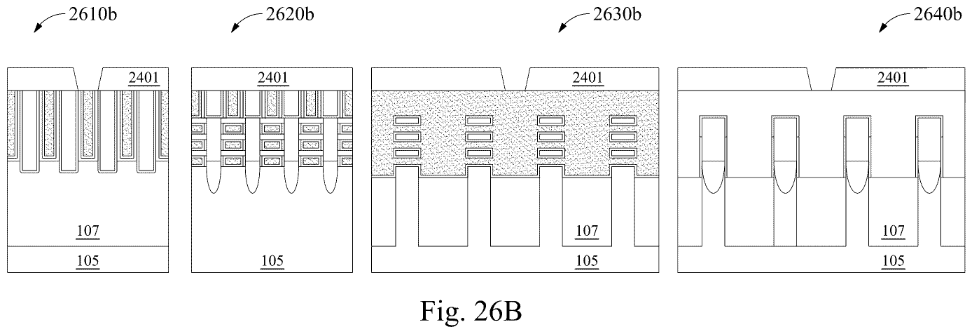

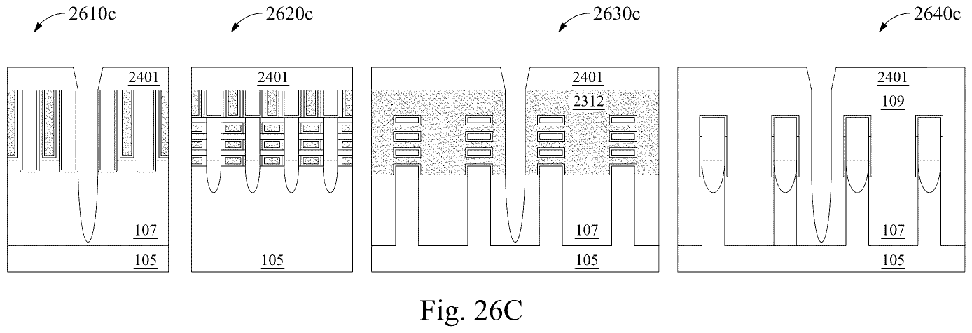

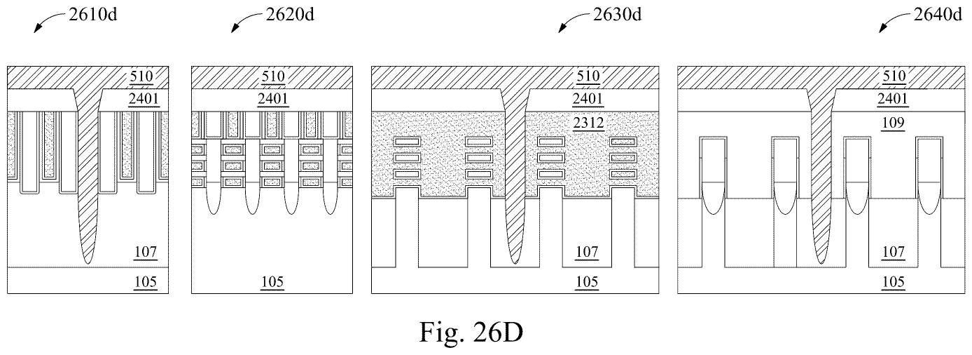

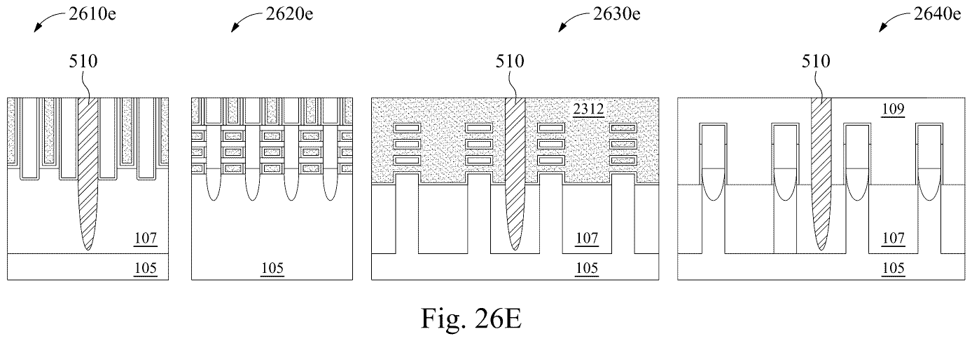

FIGS. 26A-26E illustrate a sequence of stages of a nanosheet transistor fabrication process including a application of cut metal gate techniques, according to some embodiments described herein. Each stage is shown in four views: an illustrative portion of an X-directional cut 2610 through a shallow trench isolation (STI) region of a semiconductor device, such as corresponding to cross section ‘A’ of FIG. 1A; an illustrative portion of an X-directional cut 2620 through a transistor region of the semiconductor device, such as corresponding to cross section ‘B’ of FIG. 1A; an illustrative portion of a Y-directional cut 2630 through a transistor region of the semiconductor device, such as corresponding to cross section ‘C’ of FIG. 1A; and an illustrative portion of a Y-directional cut 2640 through an EPI region of the semiconductor device, such as corresponding to cross section ‘D’ of FIG. 1A, respectively. For example, a first stage is represented by FIG. 26A and includes cross-sectional views 2610a, 2620a, 2630a, and 2640a. The stages represented by FIGS. 26A-26E are not intended to show every stage.

FIG. 26A illustrates a lithography patterning stage. A preceding stage is assumed in which a hard mask layer is deposited over the surface of the wafer. Although a particular set of layers is illustrated, the lithography can involve a two-layer, three-layer, tetralayer, or other process. As illustrated, a bottom layer 2402, a middle layer 2403, and a photoresist layer 2404 are deposited, and the photoresist layer 2404 is patterned to facilitate etching in the location of the portion of the metal gate line 130 to be cut. FIG. 26B illustrates a first etching stage to form an opening through the hard mask layer 2401 in the desired location corresponding to the portion of the metal gate line 130 to be cut. FIG. 26C illustrates a second etching stage for effectively removing the selected portion of the metal gate line 130. In FIG. 26D, a dielectric material 510 is deposited in the etched region. FIG. 26E shows a CMP stage for planarizing the wafer surface.

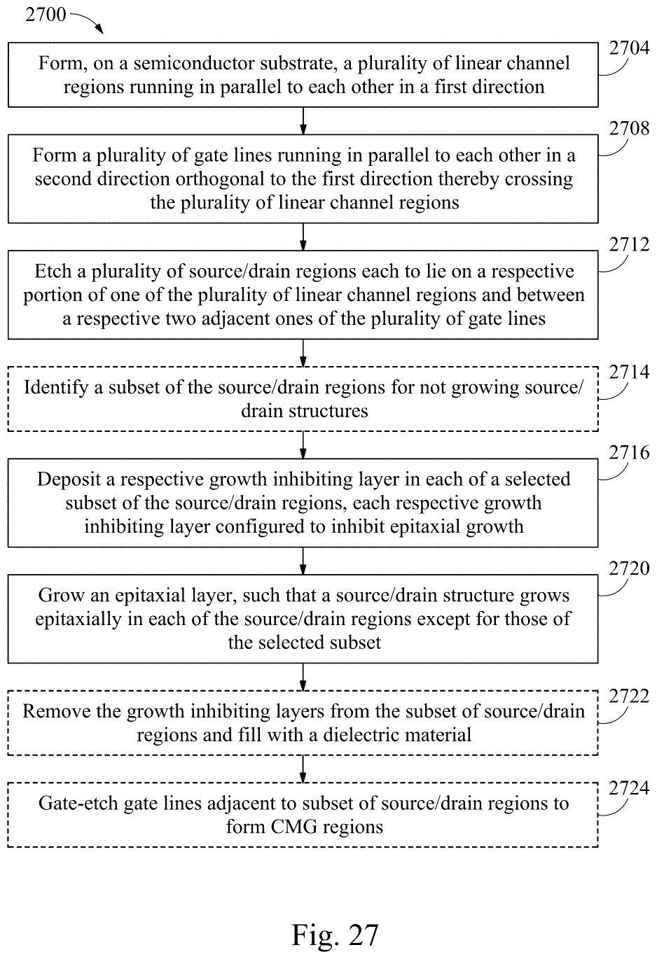

FIG. 27 shows a flow diagram of an illustrative method 2700, according to embodiments described herein. Embodiments begin at stage 2704 by forming, on a semiconductor substrate, a plurality of linear channel regions running in parallel to each other in a first direction (e.g., in an X direction according to the convention of FIG. 1A). At stage 2708, embodiments can form a plurality of gate lines running in parallel to each other in a second direction orthogonal to the first direction thereby crossing the plurality of linear channel regions (e.g., running in a Y direction according to the convention of FIG. 1A).

At stage 2712, embodiments etch a plurality of source/drain regions each to lie on a respective portion of one of the plurality of linear channel regions and between a respective two adjacent ones of the plurality of gate lines. For example, as illustrated in FIG. 1A, for each particular source/drain region: a respective first adjacent source/drain region lies on a respective first adjacent linear channel region adjacent to the particular source/drain region in the positive Y direction; a respective second adjacent source/drain region lies on a respective second adjacent linear channel region adjacent to the particular source/drain region in the negative Y direction; a respective first adjacent metal gate line of the respective two adjacent ones of the plurality of metal gate lines is adjacent to the particular source/drain region in the positive X direction; and a respective second adjacent metal gate line of the respective two adjacent ones of the plurality of metal gate lines is adjacent to the particular source/drain region in the negative X direction.

At stage 2716, embodiments deposit a respective growth inhibiting layer in each of a selected subset of the source/drain regions. Each respective growth inhibiting layer is configured to inhibit epitaxial growth. In one implementation, the growth inhibiting layers are made of aluminum oxide. In other implementations, the growth inhibiting layers are made of any material having a sufficient lattice mismatch with that of the semiconductor material used for epitaxial growth that such epitaxial growth is inhibited. As used herein in this context, references to epitaxial growth being “inhibited” means that essentially no epitaxial growth occurs.

At stage 2720, embodiments grow an epitaxial layer. For example, chemical vapor deposition (CVD), or another suitable deposition technique, is used to deposit a thin layer of crystalline silicon onto the substrate and/or other exposed semiconductor. This deposited layer has a crystal lattice structure that closely matches that of the exposed semiconductor material on which epitaxial growth is desired. As described herein, at this stage in the method 2700, each etched source/drain region not coated by a growth inhibiting layer will have exposed semiconductor material at least in edges of sandwiched layers of the linear channel region that intersect with the etched source/drain region. In some implementations (e.g., those without a bottom isolation region), a portion of the substrate is also exposed at the bottom of the etched source/drain region. Epitaxial growth will begin from those areas of exposed semiconductor material and will continue to grow source/drain structures. For example, the etching exposes, in each source/drain region, semiconductor material having a first lattice structure; the respective growth inhibiting layer in each of a selected subset of the source/drain regions is made of a material having a second lattice structure that is “epitaxially mismatched” to the first lattice structure; and epitaxial layer is made of a material having a third lattice structure that is “epitaxially matched” to the first lattice structure. The term “epitaxially mismatched” is used to mean that there is a sufficiently large mismatch in the lattice structures of two materials so that coherent epitaxial growth will not occur. In contrast, the term “epitaxially matched” is used to mean that there is a sufficiently low mismatch in the lattice structures of two materials so that coherent epitaxial growth will occur. It is assumed herein that the epitaxial growth includes any doping needed to electrically establish the grown regions as source/drain structures. For example, during or after the epitaxial layer deposition, dopants are introduced to modify the electrical properties of the silicon as part of the CVD process (e.g., in situ), through ion implantation followed by annealing., etc. Ultimately, source/drain structures grow epitaxially in each of the source/drain regions except for those of the selected subset (where such growth is prevented by the growth inhibiting layer).

Though not explicitly shown, some embodiments of the method 2700 begin with providing a wafer to which implementations of stages 2704 and 2708 have already been performed. For example, such embodiments begin by providing a wafer that has: a plurality of linear channel regions running in parallel to each other in an X direction, and formed on a substrate to extend in a positive Z direction from the substrate, the Z direction being orthogonal to the X direction; and a plurality of gate lines running in parallel to each other in a Y direction orthogonal to the X and Z directions, the gate lines made of a gate material and disposed on the linear channel regions to form a network of fin arrangements. In such embodiments, the method 2700 continues by etching the source/drain regions at stage 2712, depositing the respective growth inhibiting layers at stage 2716 and growing the epitaxial layer at stage 2720.

Though not explicitly shown, some embodiments of the method 2700 begin with providing a wafer to which implementations of at least stages 2704-2712 have already been performed. For example, such embodiments begin by providing a wafer that has an array of etched source/drain regions, each lying along a linear channel region of a plurality of linear channel regions running in parallel to each other in an X direction on a substrate of the wafer, and disposed between respective first and second adjacent gate lines of a plurality of gate lines running in parallel to each other in a Y direction orthogonal to the X direction on the substrate of the wafer. In such embodiments, the method 2700 continues by depositing the respective growth inhibiting layers at stage 2716 and growing the epitaxial layer at stage 2720.

In some embodiments, at stage 2714 (prior to stage 2716), the method 2700 includes identifying a first subset of the source/drain regions for growing source/drain structures and a second subset of the source/drain regions for not growing source/drain structures. In such embodiments, the depositing in stage 2716 involves depositing the respective growth inhibiting layer in each of the second subset of the source/drain regions, such that source/drain structures grow epitaxially in each of the first subset of source/drain regions and are inhibited from growth in each of the second subset of source/drain regions.

Some embodiments, at stage 2722, subsequent to growing the epitaxial layer in stage 2720, remove the respective growth inhibiting layer from the source/drain region and fill the source/drain region with a dielectric material. For example, the dielectric material can be ILD material 109.

As described herein, embodiments combine EPI patterning processes with CMG processes to selectively disable transistors in a semiconductor device. The EPI patterning process can be characterized by stages 2716 and 2720 of the method 2700. In addition to stages 2716 and 2720, the EPI patterning process can be construed as further including any one or more of stages 2704-2714 and/or 2722. Some embodiments of the method 2700 can further include implementing CMG at stage 2724. As illustrated, at stage 2724, for each of the subset of source/drain regions where no source/drain structure was grown, embodiments can gate-etch a portion of each of the adjacent gate lines to form a cut metal gate (CMG) region in each of adjacent gate lines. The CMG regions effectively form local electrical discontinuities in the gate lines to isolate disabled transistors.

For example, FIGS. 8-12 show several implementations of performing stage 2724 in context of EPI patterning. In some implementations, the gate-etching involves forming a CMG cut across both adjacent gate lines in a region of the gate lines that is between the linear channel region on which the disabled source/drain region lies and the next-adjacent linear channel region (i.e., to the +Y or −Y direction in the convention of FIG. 1A). In some implementations, the gate-etching involves forming a CMG cut across both adjacent gate lines in regions of the gate lines that are between the linear channel region on which the disabled source/drain region lies and both next-adjacent linear channel regions (i.e., to the +Y and −Y direction in the convention of FIG. 1A). In some implementations, each CMG cut is a single contiguous cut across both gate lines. In other implementations, each gate line is cut separately. In some implementations, the disabled source/drain region extends (i.e., in the +Y and/or −Y direction) until it intersects with the CMG cut(s). In other implementations, the disabled source/drain region is separate from (i.e., does not intersect with) the CMG cut(s).

It is assumed that the gate lines, when gate-etched in stage 2724, are metal gate lines. As described herein, embodiments of the EPI patterning portion of the method 2700 can be performed prior to depositing metal gate lines. In such cases, the gate lines formed in stage 2708 are made of a dummy gate material, such as polysilicon. This can be seen, for example, in FIGS. 23A-23R. In such cases, though not explicitly shown, embodiments of the method 2700 can include, subsequent to the growing the epitaxial layer in stage 2720 and prior to gate-etching in stage 2724, replacing the dummy gate material with a metal gate material to convert the plurality of dummy gate lines to a plurality of metal gate lines.

Further, although not explicitly shown, the method 2700 can include any other suitable prior and/or intermediate fabrication stages, including any of the stages shown in FIG. 23A 23U, 24A-24H, or 25A-25H. For example, prior to the etching in stage 2712, each of the linear channel regions can be made of at least two silicon-germanium interposer layers each sandwiched between adjacent channel material (semiconductor) layers. In such cases, the method 2700 can include, subsequent to the etching at stage 2712, replacing the silicon-germanium interposer layers with corresponding oxide interposer layers.

### Avoiding Layout-Dependent Effects of Transistor Patterning in the Scaling Limit

Embodiments described above were generally illustrated as having relatively consistent pitch size and spacing across the transistor array (e.g., as illustrated in FIG. 2B), effectively yielding transistors of consistent channel length. In some cases, it is desirable to have a layout that includes transistors with different channel lengths. For example, transistors with shorter channel lengths tend to be faster, making them suitable for high-speed critical paths, but they can consume more power due to increased leakage currents. In contrast, transistors with longer channel lengths tend to be more power-efficient and reliable, making them ideal for low-power circuits and components that require higher voltage operation or better resistance to wear-out mechanisms. A semiconductor with a large nanosheet transistor array can be patterned to include both types of transistors.

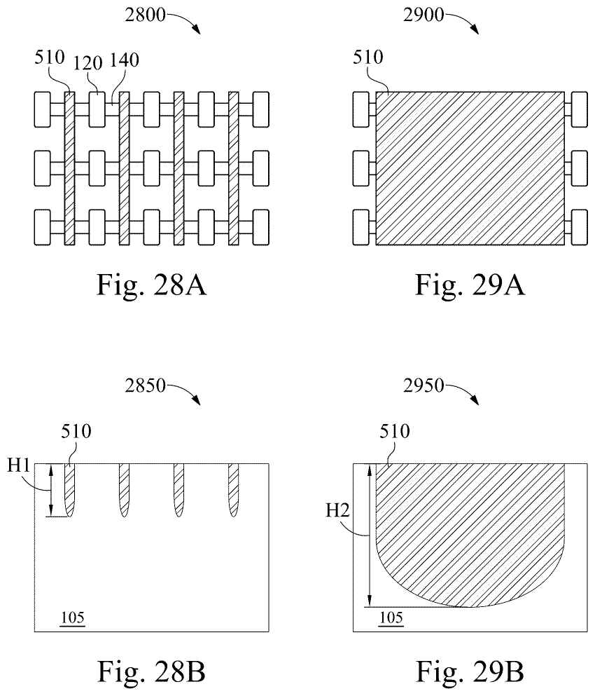

FIG. 28A-29B show examples of transistors with different channel lengths patterned using CPODE or CMODE techniques. Each of FIGS. 28A and 29A shows a top-down view 2800 and 2900, respectively, of a respective portion of an example transistor array. As described above (e.g., FIG. 1A), each transistor is made up of a pair of source/drain structures 120 disposed on a linear channel region 140 on either side of a metal gate line 130 (not shown because it is assumed to have been removed by CMODE or CPODE). In FIG. 28A, the illustrated portion of the array includes three rows, each having four short-channel transistors (all disabled). In FIG. 29A, the illustrated portion of the array includes three rows, each having one long-channel transistor (disabled).

FIG. 28B shows a cross-sectional view 2850 through the portion of the array shown in FIG. 28A, and FIG. 29B shows a cross-sectional view 2950 through the portion of the array shown in FIG. 29A. As illustrated, the CMODE or CPODE process essentially leaves gate line regions etched away and filled with dielectric material 510. The dielectric material 510 can be any suitable dielectric material 510. In context of the short-channel devices of FIGS. 28A and 28B, etching away the gate line region leaves a well of a first depth, H1. In context of the long-channel devices of FIGS. 29A and 29B, etching away the gate line region leaves a well of a second depth, H2. As illustrated, because of the larger channel width, H2 is appreciably deeper than H1.

This, in addition to layout-dependent effects of CPODE and CMODE (e.g., and other conventional transistor isolation approaches) described above, such as PR peeling, scum defects, EPI damage, etc., the difference between H1 and H2 can cause layout-dependent concerns. One effect of this difference is that it can be difficult or impractical to etch short-and long-channel devices at the same time due to etch micro-loading effects (substantial differences between depth and CD bias). Another effect of this difference is that, if H2 becomes too large, the etching can result in damage to the substrate 105 and/or other structures.

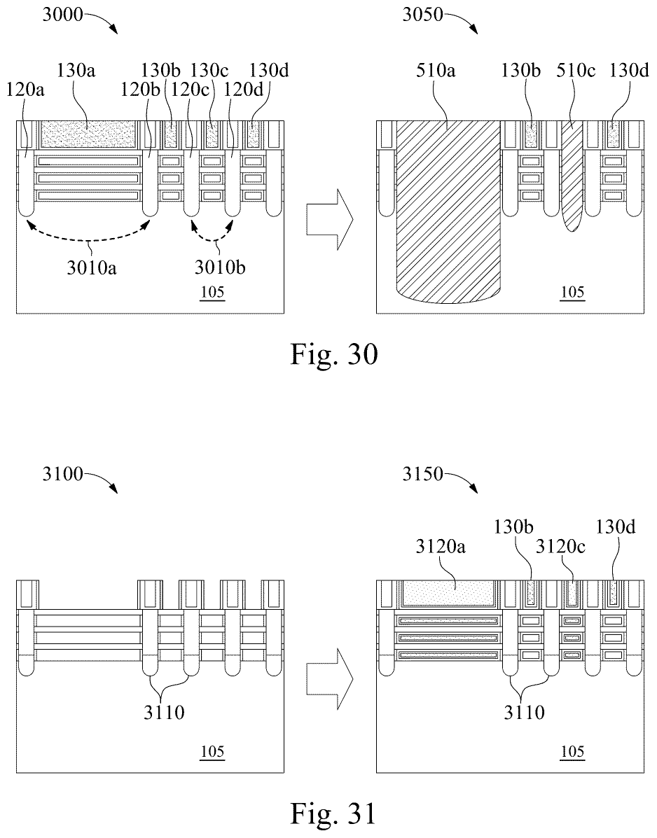

Embodiments described herein use gates with different gate threshold voltages VTH to effectively disable selected transistors of different channel lengths without relying on CPODE, CMODE, or the like. For context, FIG. 30 shows a cross-sectional view before gate-etching 3000 and a corresponding cross-sectional view after gate-etching 3050. In the cross-sectional view before gate-etching 3000, several source/drain regions 120 and metal gate lines 130 (i.e., corresponding to respective portions of the metal gate layer 2312) are shown on a substrate 105. Different pitch sizes are shown. For example, metal gate line 130a corresponds to a long-channel device, and metal gate lines 130b, 130c, and 130d correspond to short-channel devices. The cross-sectional view after gate-etching 3050 represents selective disabling of metal gate lines 130a and 130c. As described with reference to FIGS. 28B and 29B, etching of metal gate line 130a results in a relatively deep well (filled with dielectric material 510a), as compared to the result of etching metal gate line 130c (filled with dielectric material 510c).

FIG. 31 shows an example of transistor isolation by gate differentiation, according to some embodiments described herein. Similar to FIG. 30, FIG. 31 shows a cross-sectional view before gate differentiation 3100 and a corresponding cross-sectional view after gate differentiation 3150. For example, the cross-sectional view before gate differentiation 3100 represents a stage in fabrication after dummy gate material (e.g., and interposers) has been removed in preparation for depositing metal gate lines (e.g., similar to the stages of FIGS. 24G, 25C, etc.). The cross-sectional view after gate differentiation 3150 shows enabled metal gate lines 130 deposited using a gate material having a first threshold voltage (V_{TH-A}) to form enabled transistors, and disabled metal gate lines 3120 deposited using a gate material having a second threshold voltage (V_{TH-B}) to form disabled transistors. It can be seen that the approach effectively avoids concerns arising from different well depths regardless of channel length.

Another layout-dependent concern arises from leakage currents through the substrate 105 between adjacent source/drain structures 120. For example, the cross-sectional view before gate-etching 3000 of FIG. 30 illustrates leakage current 3010a between source/drain structures 120a and 120b, and leakage current 3010b between source/drain structures 120c and 120d. Leakage current 3010 tends to increase with a decrease in pitch size (i.e., leakage current 3010a will tend to be appreciably less than leakage current 3010b), such that the leakage current 3010 is layout-dependent.

As illustrated in FIG. 31, embodiments described herein include bottom isolation dielectrics 3110. The bottom isolation dielectrics 3110 are disposed below each source/drain structure 120 to electrically isolate the source drain structures 120 from the dielectric. This mitigates or eliminates leakage current 3010, permitting current flow between adjacent source/drain structures 120 only via the linear channel regions.

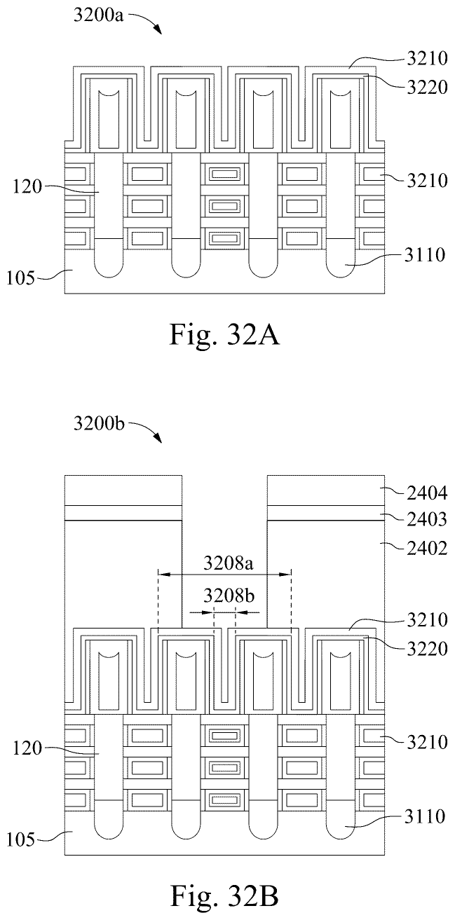

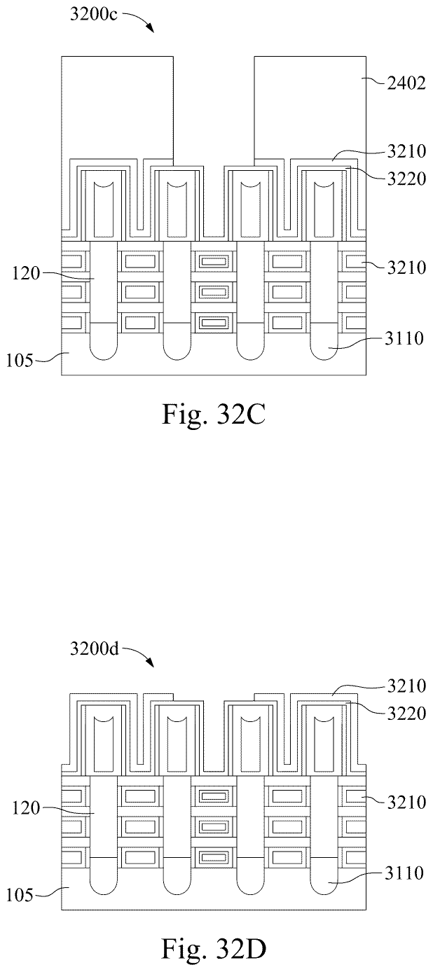

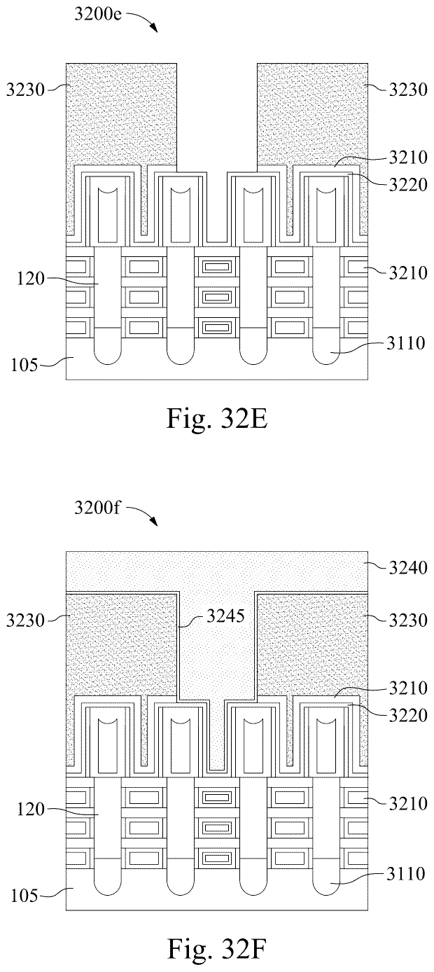

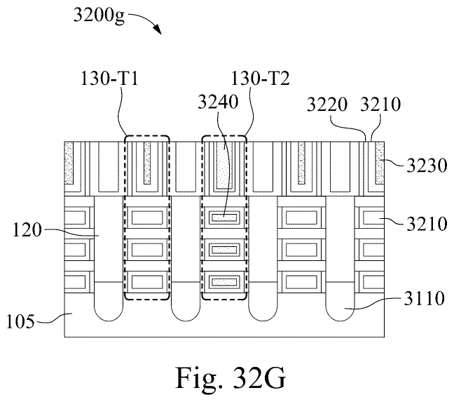

FIGS. 32A-32G show selected stages 3200 of a fabrication process for creating gate structures with different threshold voltages (V_{TH}), according to embodiments described herein. Each stage 3200 is illustrated by a portion of an X-directional cut through a transistor region of a semiconductor device, such as corresponding to cross section ‘B’ of FIG. 1A, cuts 2320, cuts 2420, etc. Beginning at stage 3200a of FIG. 32A, the X-directional cut shows a substrate 105 with several epitaxially grown source/drain structures 120, each electrically isolated from the substrate 105 by a bottom isolation dielectric 3110. A first metal layer 3210 has been deposited on top of gate dielectrics 3220.

In stage 3200b of FIG. 32B, lithography patterning is applied to deposit a bottom layer 2402, middle layer 2403, and photoresist layer 2404. Those layers are patterned to cover certain portions of the first metal layer 3210 and gate dielectrics 3220, and to leave selected regions exposed for etching.

In stage 3200c of FIG. 32C, the exposed region(s) of the first metal layer 3210 and gate dielectrics 3220 is etched. In stage 3200d of FIG. 32D, the remaining bottom layer 2402 is removed. As explained below, the unetched regions correspond to regions that will have first metal gates with a first threshold voltage (V_{TH-A}), and the etched regions correspond to regions that will have second metal gates with a second threshold voltage (V_{TH-B}) that is sufficiently different from the first threshold voltage (V_{TH-A}) as to allow the first metal gates to be turned on or off without turning on or off the second metal gates.

As noted above, a conventional CPODE, CMODE, or similar process must operate within a very tight tolerance to be effective. For example, if the patterned region is too narrow, portions of the metal may not be removed and/or scum defects can occur; if the patterned region is too large, the source/drain structures 120 can be damaged and/or PR peeling can occur. Referring back to FIG. 32B, the width of the patterned region for CMODE, CPODE, or similar processes tightly corresponds to dimension 3208b. However, the novel gate differentiation approach described herein permits an appreciably larger tolerance. For example, any patterned region width between dimension 3208b and dimension 3208a can be used to remove the desired region of the first metal gate 3210 without concern for scum defects, PR peeling, damage to source/drain structures 120, etc.

In stage 3200e of FIG. 32E, a second metal layer 3230 is deposited on the first metal layer 3210 (i.e., the unetched portions). The second metal layer 3230 (e.g., and/or the first metal layer 3210) can be an implementation of metal gate layer 2312 in some embodiments described above. In stage 3200f of FIG. 32F, a third metal layer 3240 is deposited. Embodiments can deposit a glue layer 3245 under portions of the third metal layer 3240.

In stage 3200g of FIG. 32G, CMP is applied to planarize the surface of the semiconductor device and to effectively form first and second metal gate lines 130. In particular, some portions of some metal gate lines 130 are made of one or more first metals (e.g., first metal layer 3210 and second metal layer 3230) to form a first-threshold metal gate line 130-T1 with a first threshold voltage (V_{TH-A}), and different portions of the same and/or different metal gate lines 130 are made of one or more second metals (e.g., third metal layer 3240) to form a second-threshold metal gate line 130-T2 with a second threshold voltage (V_{TH-b}). Although the first-threshold metal gate line 130-T1 is shown as made up of two different metals, and the second-threshold metal gate line 130-T2 is shown as made up of a single metal, different types of metal gate lines 130 can be implemented using any one or more layers of metals to produce the desired threshold voltages for those types. Further, although the process of FIGS. 32A-32G creates gate structures with two different threshold voltages, the process can be repeated, as needed, to create any suitable number of threshold-differentiated gate structures.

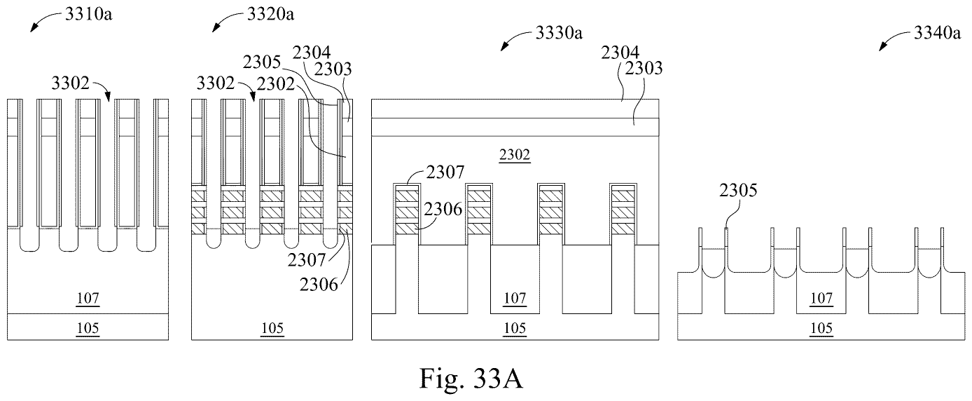

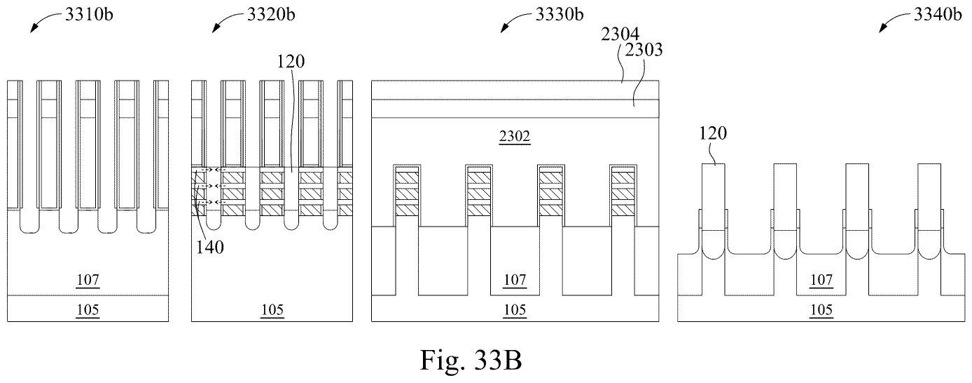

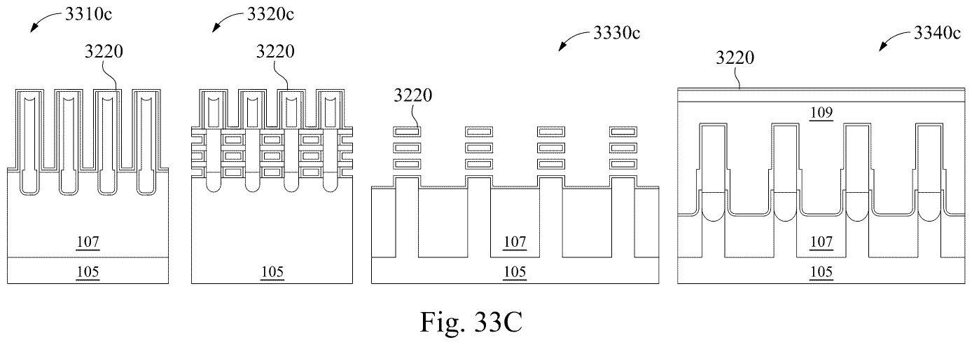

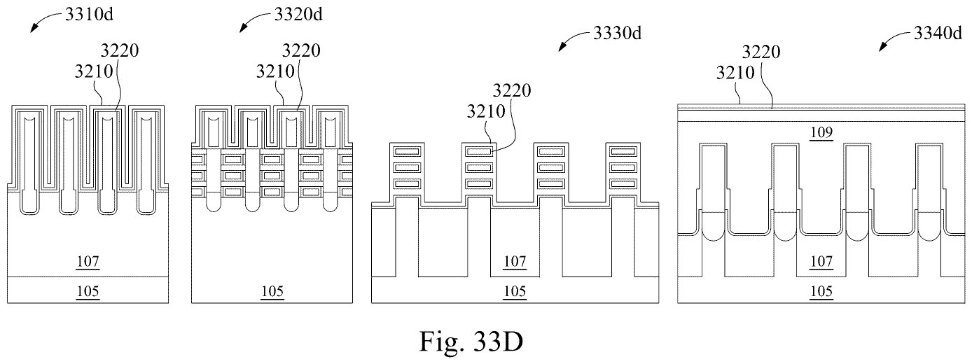

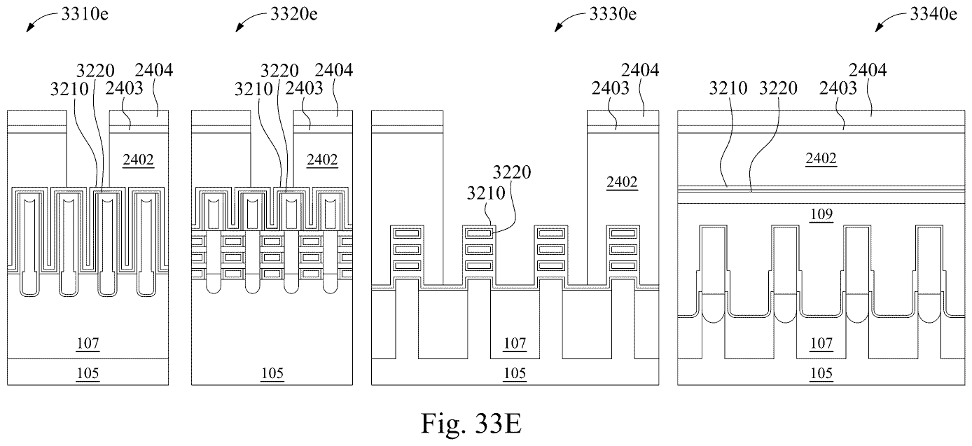

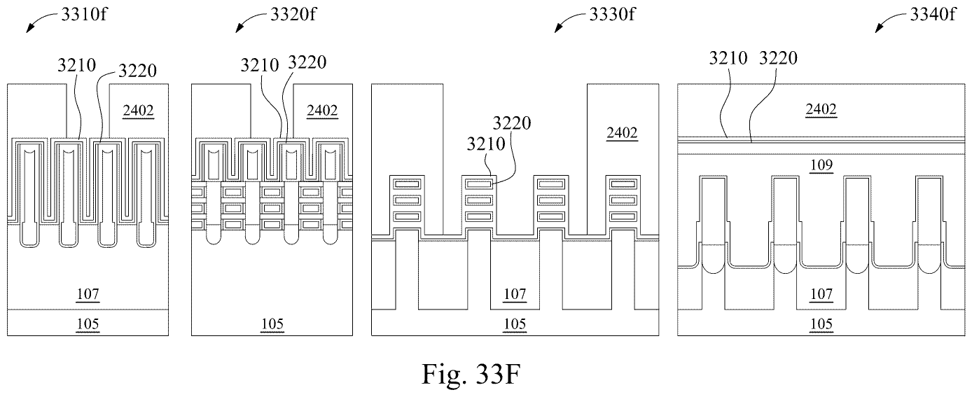

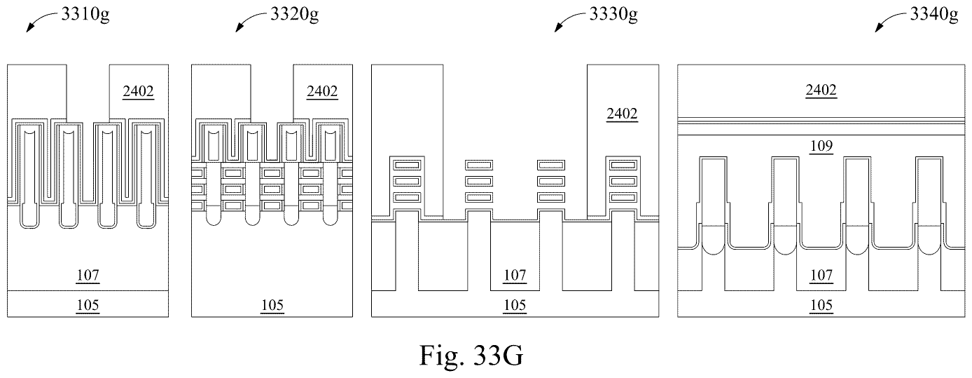

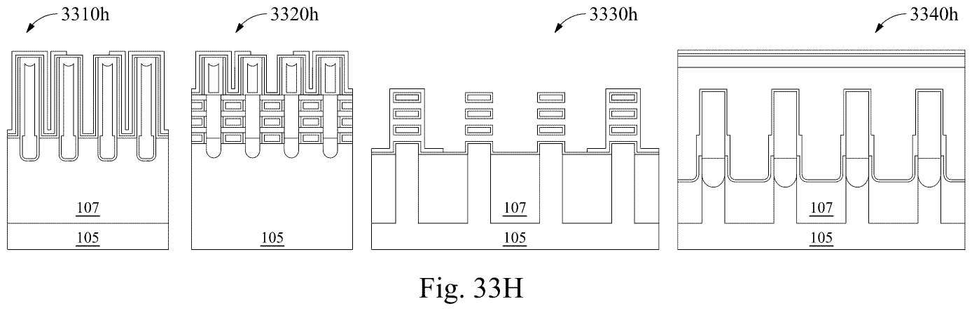

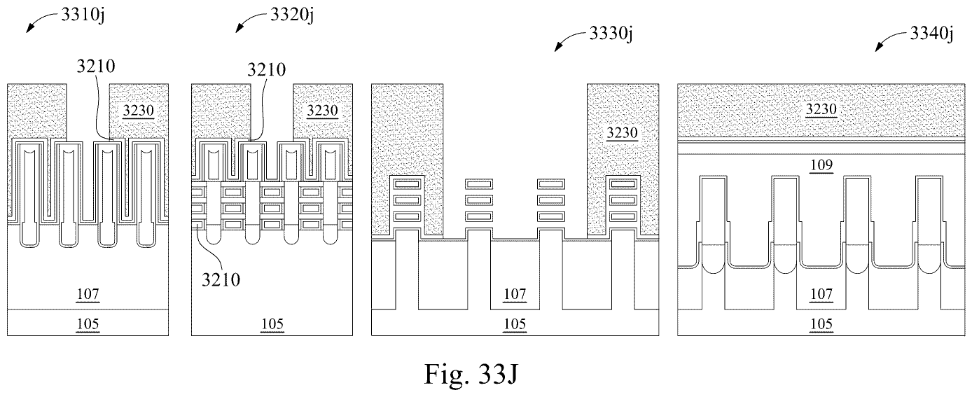

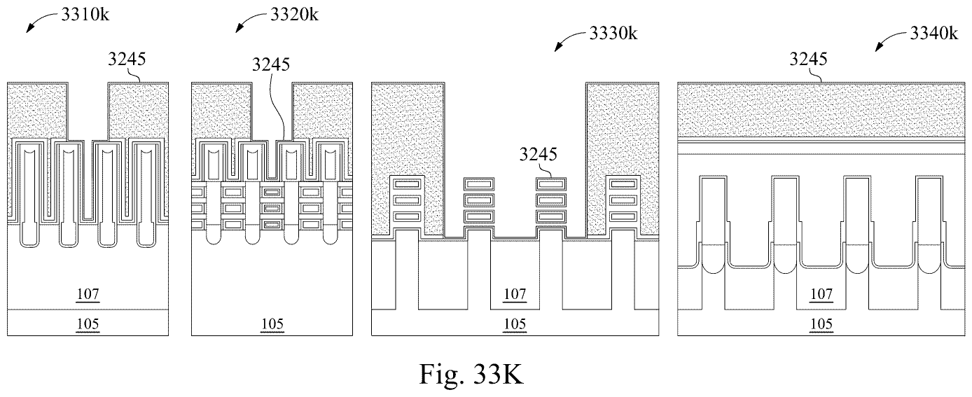

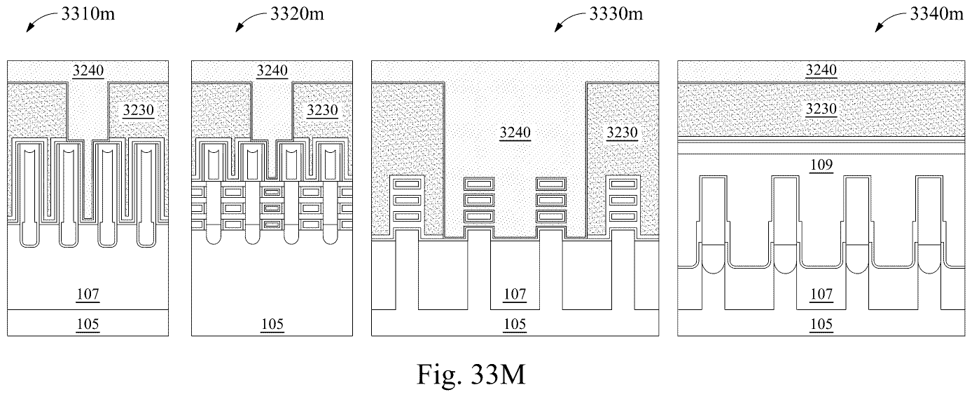

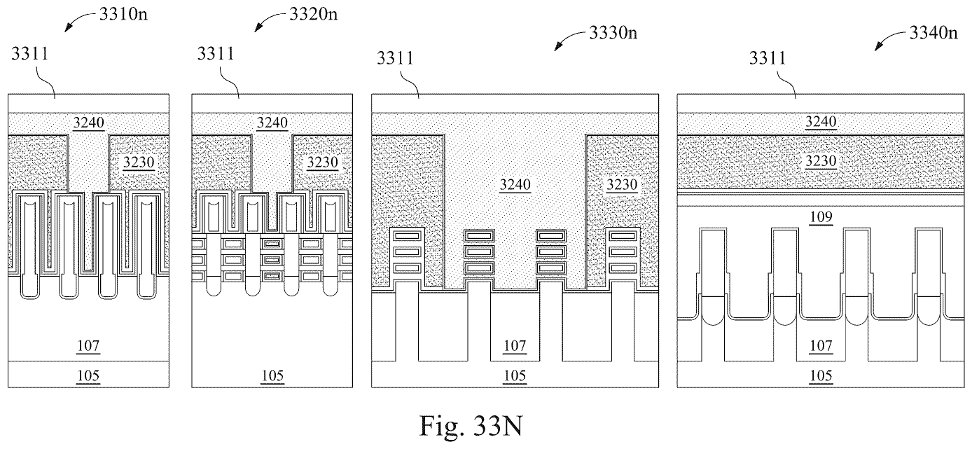

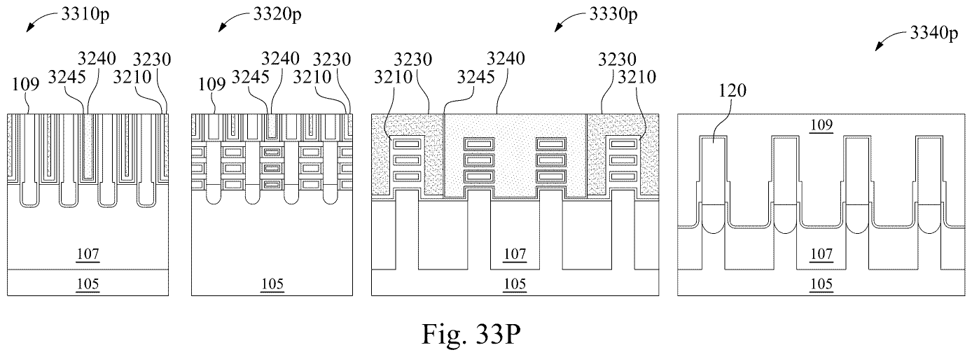

FIGS. 33A-33P illustrate a sequence of stages of a semiconductor device fabrication process including gate differentiation and bottom isolation dielectric deposition, according to some embodiments described herein. Each stage is shown in four views: an illustrative portion of an X-directional cut 3310 through a shallow trench isolation (STI) region of a semiconductor device, such as corresponding to cross section ‘A’ of FIG. 1A; an illustrative portion of an X-directional cut 3320 through a transistor region of the semiconductor device, such as corresponding to cross section ‘B’ of FIG. 1A; an illustrative portion of a Y-directional cut 3330 through a transistor region of the semiconductor device, such as corresponding to cross section ‘C’ of FIG. 1A; and an illustrative portion of a Y-directional cut 3340 through an EPI region of the semiconductor device, such as corresponding to cross section ‘D’ of FIG. 1A; respectively. For example, a first stage is represented by FIG. 33A and includes cross-sectional views 3310a, 3320a, 3330a, and 3340a. The stages represented by FIGS. 33A-33P are not intended to show every stage; rather the focus is on stages relevant to gate differentiation and bottom isolation dielectric deposition. For example, the stage represented in FIG. 33A can follow the stages represented in FIGS. 23A-23F .

FIG. 33A illustrates a stage in which bottom isolation dielectrics 3110 are deposited and trimmed. For context, the cross-sectional views show several illustrative layers and materials, including a substrate 105, an STI layer 107, a polysilicon (e.g., dummy gate) layer 2302, a silicon nitride layer 2303, a silicon oxide layer 2304, a spacer layer 2305, oxide interposer layers 2306, and interspacer material 2307. Prior source/drain region etching has left wells 3302 in which source/drain structures 120 will be epitaxially grown, and bottom isolation dielectrics 3110 are deposited at the bottom of each such well 3302. In FIG. 33B, the source/drain structures 120 are epitaxially grown. Because the wells 3302 are isolated from the substrate, the epitaxial growth tends to be from the semiconductor material of the linear channel region 140 layers on the sides of the wells, as indicated by dashed arrows.

Embodiments can proceed in a manner similar to that illustrated in FIGS. 23K-23T , including depositing a capping etch layer (CEL) material, depositing an ILD material 109, performing CMP, forming recesses in the ILD material 109 layer at the source/drain structure 120 locations, depositing an ILD capping layer 2311 over the ILD material 109 (including in the recesses), performing CMP again, removing the dummy gate layer 2302, and removing the oxide interposer layers 2306.

The remaining stages of FIGS. 33C-33P provide additional views and details for the stages represented by FIGS. 32A-32G . FIGS. 33C and 33D show stages in which gate dielectrics 3220 and first metal gate layers 3210 are deposited, respectively, such as in FIG. 32A. In FIG. 33E, as in stage 3200b of FIG. 32B, lithography patterning is applied to deposit a bottom layer 2402, middle layer 2403, and photoresist layer 2404, to cover certain portions of the first metal layer 3210 and gate dielectrics 3220, and to leave selected regions exposed for etching.

In FIGS. 33F-33H , as in stages 3200c and 3200d of FIG. 32C and D, the middle layer 2403 and photoresist layer 2404 are removed, the exposed region(s) of the first metal layer 3210 and gate dielectrics 3220 are etched, and the bottom layer 2402 is removed. In FIG. 33J, as in stage 3200e of FIG. 32E, a second metal layer 3230 is deposited on the first metal layer 3210 (i.e., the unetched portions).

In FIGS. 33K-33M , as in stage 3200f of FIG. 32F, a glue layer 3245 is deposited, followed by depositing a third metal layer 3240. In FIG. 33P, as in stage 3200g of FIG. 32G, CMP is applied to planarize the surface of the semiconductor device and to effectively form first and second metal gate lines 130. As described with reference to FIG. 32G, the result of FIG. 33P is to leave some portions of some metal gate lines 130 as first-threshold metal gate lines 130-T1 with a first threshold voltage (V_{TH-A}) made of one or more first metals (e.g., first metal layer 3210 and second metal layer 3230) and different portions of the same and/or different metal gate lines 130 as second-threshold metal gate lines 130-T2 with a second threshold voltage (V_{TH-b}) made of one or more second metals (e.g., third metal layer 3240).

In some embodiments, in FIG. 33N, a capping layer 3311 (e.g., silicon nitride) can be deposited prior to CMP. The capping layer 3311 can act as a robust barrier to protect underlying materials from being damaged during the CMP process. Further, as described below, the capping layer 3311 can help with gate formation in context of longer-channel devices.

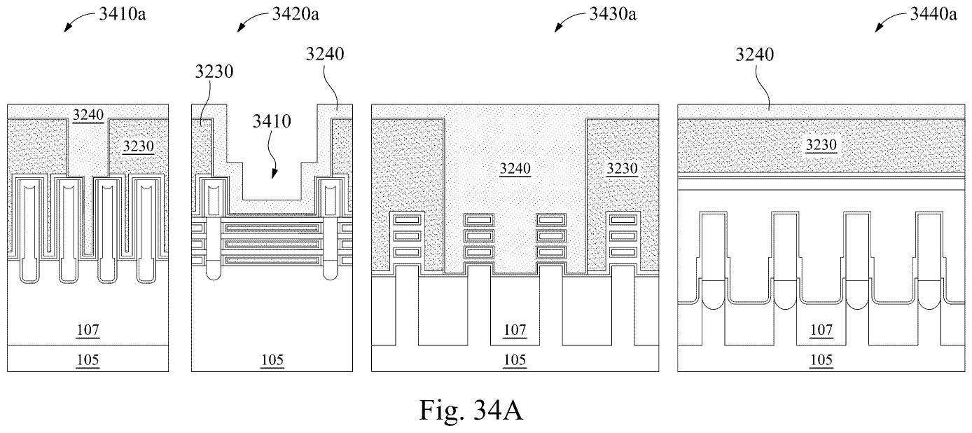

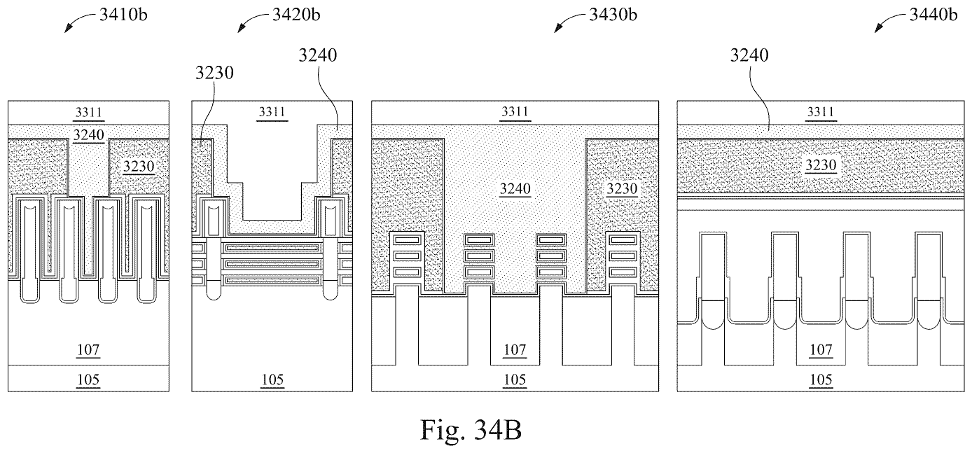

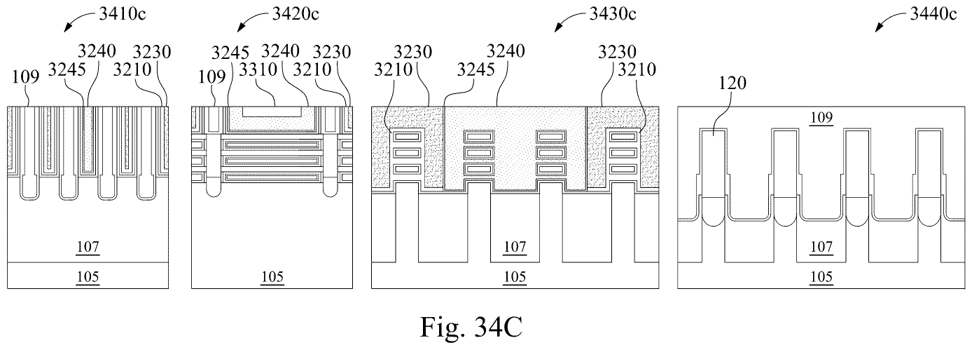

Notably, FIGS. 33A-33P show a fabrication process for a short-channel device. The process for creating a long-channel device can be substantially the same. For the sake of additional clarity, FIGS. 34A-34C show a portion of a fabrication process corresponding to FIGS. 33M-33P , respectively, as applied to a long-channel device. In FIG. 34A, as in FIG. 33M, a third metal layer 3240 is deposited. As illustrated, in regions of longer channels, the depositing in FIG. 34A can result in wells 3410 in the third metal layer 3240 (represented in view 3420a). In FIG. 34B, as in FIG. 33N, a capping layer 3311 can be deposited. As illustrated, the capping layer 3311 can fill the wells in the third metal layer 3240. In FIG. 34C, as in FIG. 33P, CMP is applied to planarize the surface of the semiconductor device and to effectively form metal gate lines 130 with first-threshold metal gate line 130-T1 portions of a first threshold voltage (V_{TH-A}) made of one or more first metals (e.g., first metal layer 3210 and second metal layer 3230) and second-threshold metal gate line 130-T2 portions of a second threshold voltage (V_{TH-b}) made of one or more second metals (e.g., third metal layer 3240).

As described above, the gate differentiation can be used to selectively disable selected transistors in a transistor array (e.g., a nanosheet transistor array, a very-small-scale fin-FET array, etc.), regardless of channel length, while avoiding common layout-dependent concerns of conventional approaches. Novel approaches described herein ca also be combined with certain conventional approaches to provide additional novel embodiments.

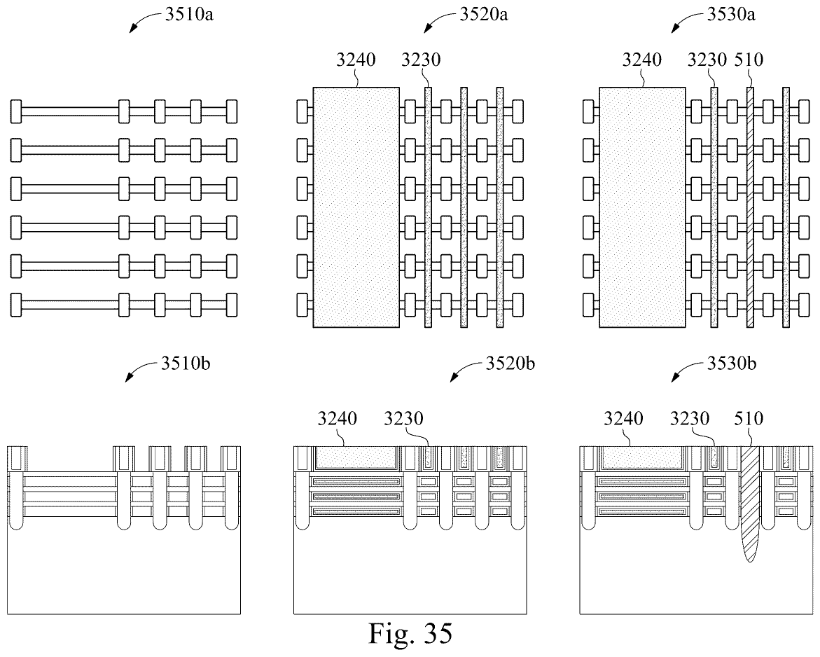

FIG. 35 shows an illustrative embodiment in which a CMODE process is combined with novel gate differentiation and bottom isolation approaches described herein. As described above, the CMODE process involves removing gate structures subsequent to gate formation. A first top-down view 3510a and a first cross-sectional view 3510b represent a stage prior to gate formation. Different channel lengths between source/drain structures 120 are represented. Bottom isolation dielectrics 3110 have been deposited, and source/drain structures 120 have been grown.

A second top-down view 3520a and a second cross-sectional view 3520b represent a stage subsequent to gate formation. A gate differentiation approach has been used to form first-threshold metal gate lines 130-1 of a first threshold voltage over the shorter channel regions, and a second-threshold metal gate line 130-2 of a second threshold voltage over the longer channel region.

A third top-down view 3530a and a third cross-sectional view 3530b represent a stage subsequent to applying CMODE to disable one of the first-threshold metal gate lines 130-1 previously formed over one of the shorter channel regions. As illustrated, the removed gate structure can be replaced with a dielectric material 510.

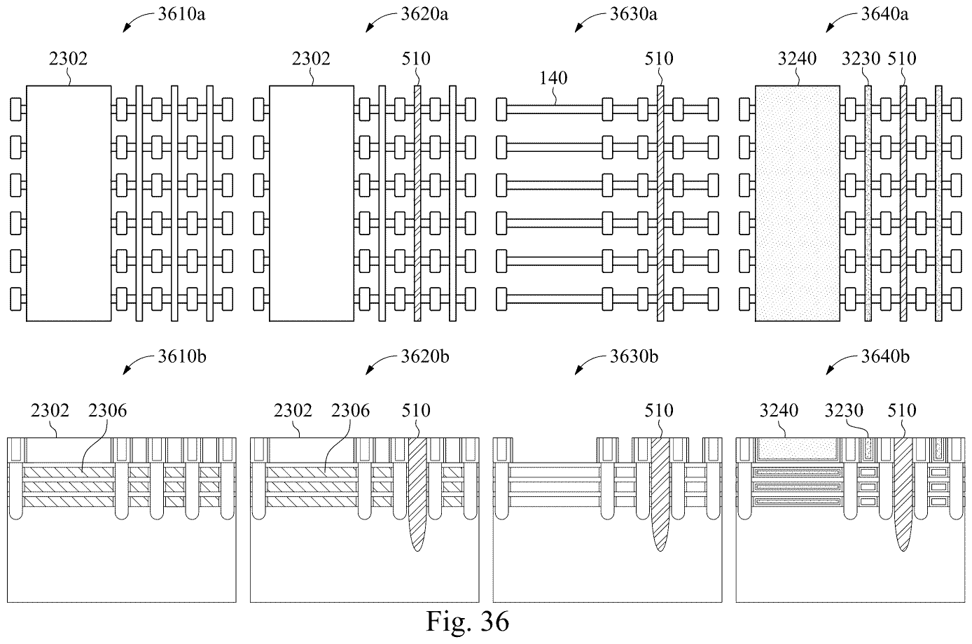

FIG. 36 shows an illustrative embodiment in which a CPODE process is combined with novel gate differentiation and bottom isolation approaches described herein. As described above, the CPODE process involves removing gate structures prior to gate formation. A first top-down view 3610a and a first cross-sectional view 3610b represent a stage in which a dummy gate layer 2303 and oxide interposer layers 2306 are present. Different channel lengths between source/drain structures 120 are represented. Bottom isolation dielectrics 3110 have been deposited, and source/drain structures 120 have been grown.

A second top-down view 3620a and a second cross-sectional view 3620b represent a stage subsequent to applying CPODE to pre-disable one of the gate regions. As illustrated, a region of the dummy gate layer 2303 and oxide interposer layers 2306 is removed and replaced with a dielectric material 510.

A third top-down view 3630a and a third cross-sectional view 3630b represent a stage after CPODE, but still prior to gate formation. The dummy gate layer 2303 and oxide interposer layers 2306 have been removed, leaving different channel lengths between source/drain structures 120. This stage is similar to the stage represented in views 3510 of FIG. 35, except for the dielectric material 510 region resulting from CPODE.

A fourth top-down view 3640a and a fourth cross-sectional view 3640b represent a stage subsequent to gate formation. A gate differentiation approach has been used to form first-threshold metal gate lines 130-1 of a first threshold voltage over the shorter channel regions (other than the one pre-disabled by CPODE and filled with the dielectric material 510), and a second-threshold metal gate line 130-2 of a second threshold voltage over the longer channel region. It can be seen that approaches in FIGS. 35 and 36 can produce essentially the same result.

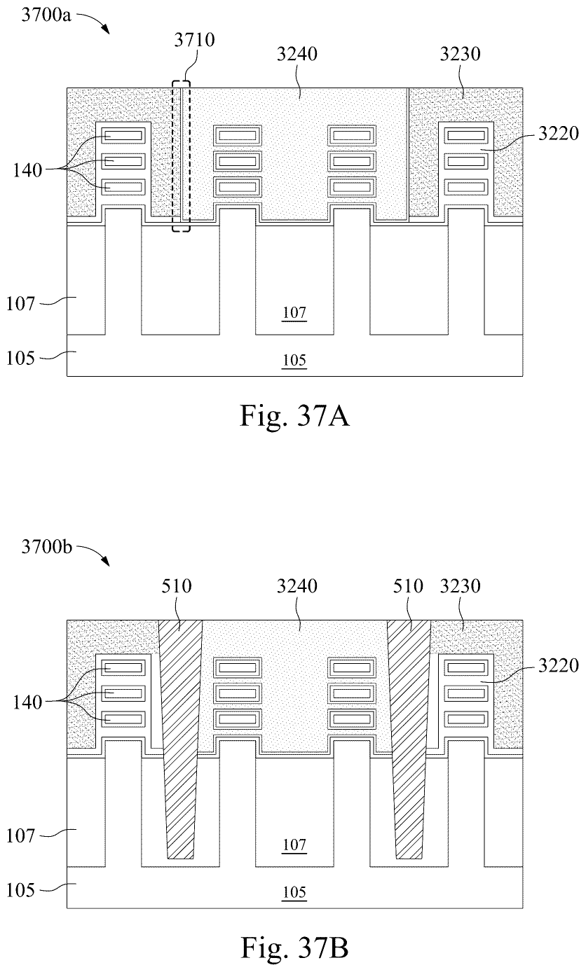

The gate differentiation approaches described herein result in metal boundary regions where one metal of a first-threshold metal gate line 130-1 and a different metal of a second-threshold metal gate line 130-2 abut one another. FIGS. 37A and 37B show an example of metal boundary regions 3710 forming as part of gate differentiation approaches described herein and use of cut metal gate (CMG) approaches to remove such regions. In FIG. 37A, a cross-sectional view 3700a shows metal boundary regions 3710 resulting from depositing of the third metal gate layer 3240 in direct contact with the second metal gate layer 3230. In such metal boundary regions 3710, there is a possibility of interdiffusion between the metals, which can tend to affect the threshold voltage in those metal boundary regions 3710.

In FIG. 37B, a cross-sectional view 3700b shows the same regions illustrated in cross-sectional view 3700b after application of a CMG process. The CMG process is used to etch CMG cuts (e.g., like CMG cuts 310 described above) in the metal boundary regions 3710. As illustrated, the CMG cuts can be filled with any suitable dielectric material 510.

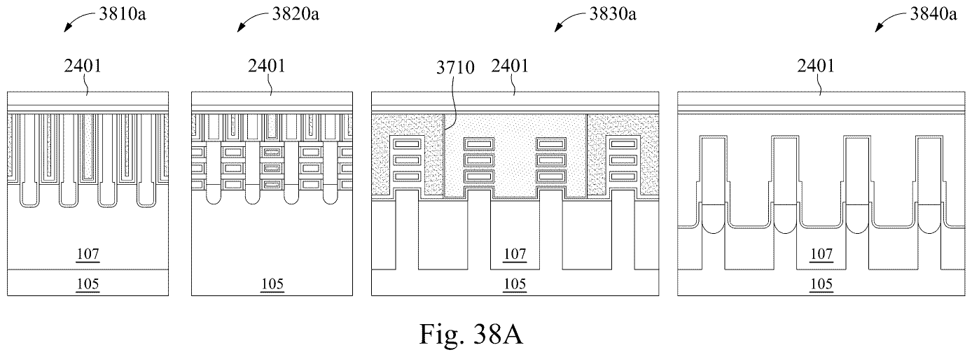

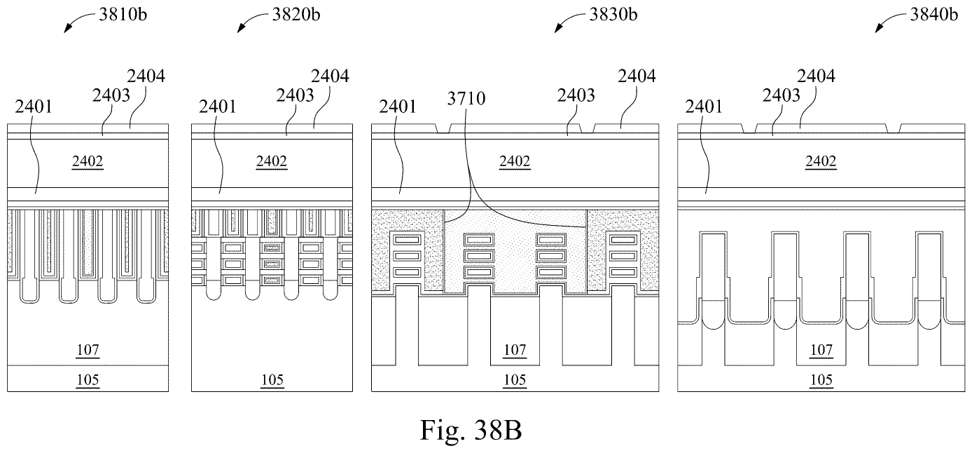

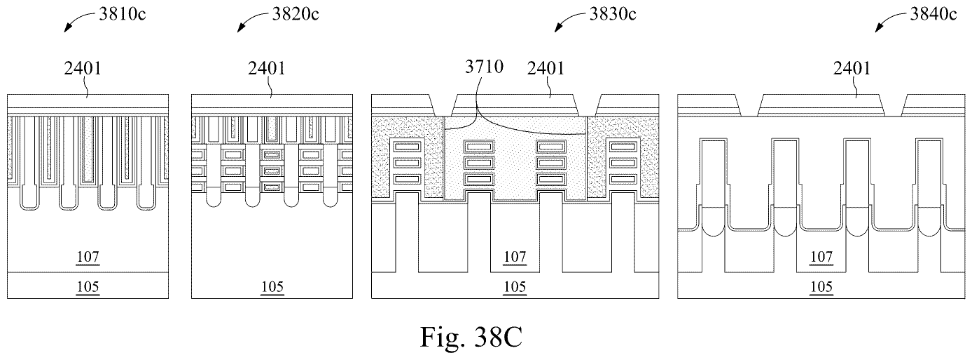

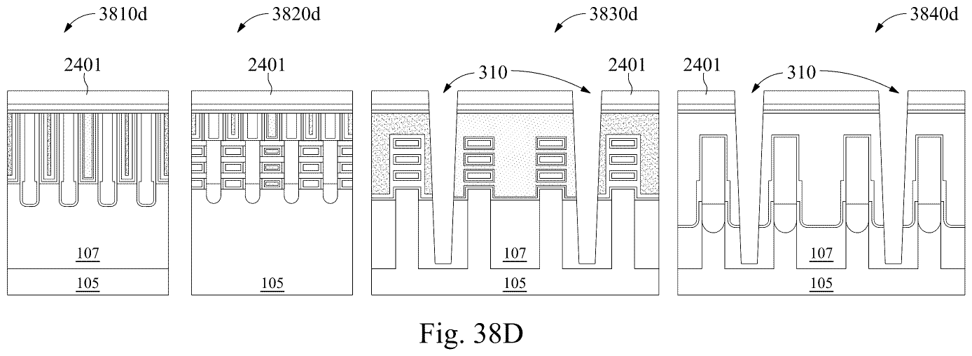

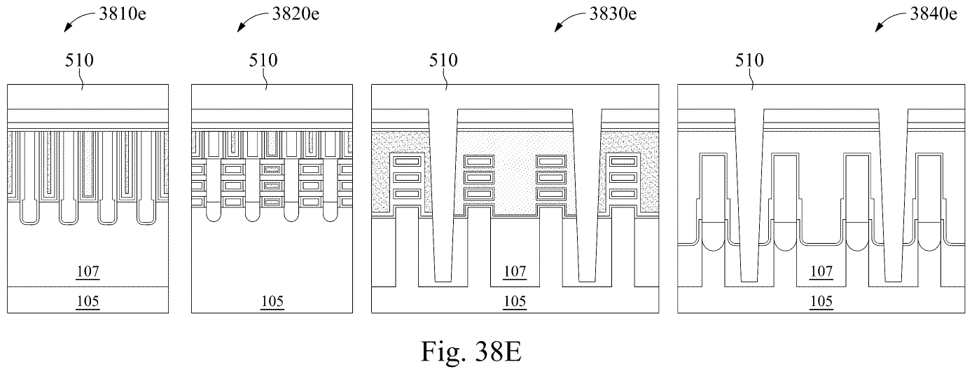

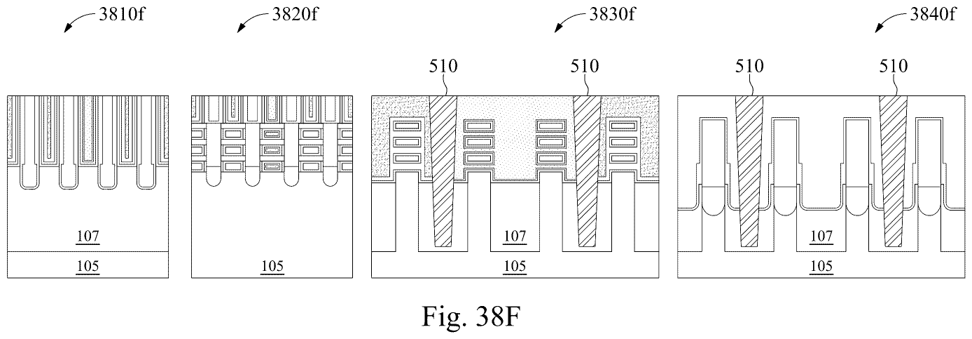

FIGS. 38A-38F illustrate a sequence of stages of a cut metal gate (CMG) process to remove metal boundary regions 3710, such as described with reference to FIGS. 37A and 37B. Each stage is shown in four views: an illustrative portion of an X-directional cut 3810 through a shallow trench isolation (STI) region of a semiconductor device, such as corresponding to cross section ‘A’ of FIG. 1A; an illustrative portion of an X-directional cut 3820 through a transistor region of the semiconductor device, such as corresponding to cross section ‘B’ of FIG. 1A; an illustrative portion of a Y-directional cut 3830 through a transistor region of the semiconductor device, such as corresponding to cross section ‘C’ of FIG. 1A; and an illustrative portion of a Y-directional cut 3840 through an EPI region of the semiconductor device, such as corresponding to cross section ‘D’ of FIG. 1A; respectively. For example, a first stage is represented by FIG. 38A and includes cross-sectional views 3810a, 3820a, 3830a, and 3840a. The stages represented by FIGS. 38A-38F are not intended to show every stage.

FIG. 38A shows a stage in which a hard mask 2401 is deposited. The hard mask 2401 is a silicon-based mask material. In FIG. 38B, lithography patterning is applied to deposit a bottom layer 2402, middle layer 2403, and photoresist layer 2404. The photoresist layer 2404 is patterned based on where CMG cuts are desired (i.e., at the metal boundary regions 3710). In FIG. 38C, the photolithography results in removal of the bottom layer 2402, middle layer 2403, and photoresist layer 2404, along with opening of correspondingly patterned regions of the hard mask 2401. In FIG. 38D, etching is performed, thereby forming CMG cuts 310 through the metal boundary regions 3710. As illustrated, the CMG cuts 310 can extend into the STI layer 107. In FIG. 38E, the CMG cuts 310 can be filled with any suitable dielectric material 510. In FIG. 38F, a CMP process can be applied to planarize the surface of the semiconductor device.

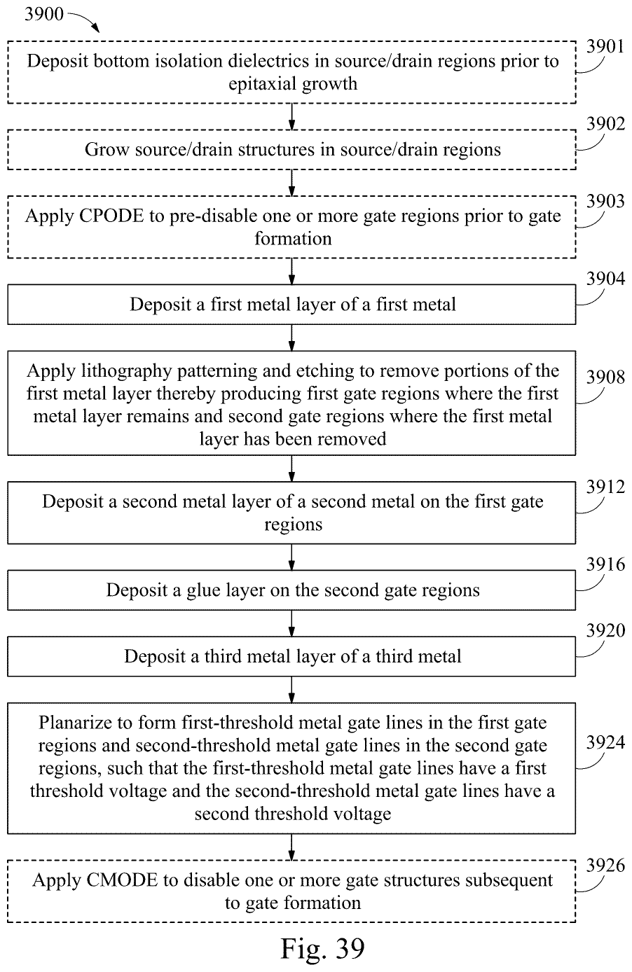

FIG. 39 shows a flow diagram of an illustrative method 3900 for partially fabricating a semiconductor device including gate differentiation and bottom isolation dielectric deposition, according to some embodiments described herein. Embodiments begin at stage 3904 by depositing first metal layers of a first metal. Stage 3904 can include depositing gate dielectrics prior to depositing the first metal gate layers. At stage 3908, embodiments can use lithography patterning and etching to remove portions of the first metal layer, thereby producing first gate regions where the first metal layer remains and second gate regions where the first metal layer has been removed. For example, a bottom layer, middle layer, and photoresist layer are deposited and patterned to cover certain portions of the first metal layer and gate dielectrics, and to leave selected regions exposed for etching. The middle layer and photoresist layer are then removed, the exposed region(s) of the first metal layer and gate dielectrics are etched, and the bottom layer is removed.

At stage 3912, embodiments can deposit second metal layers of a second metal on the first gate regions (i.e., on the unetched portions of the first metal layer. At stage 3916, embodiments can deposit a glue layer on the second gate regions. At stage 3920, embodiments can deposit third metal layers of a third metal. The third metal covers at least the second gate regions (e.g., covering the glue layer).

At stage 3924, embodiments can planarize the surface of the semiconductor device to form first-threshold metal gate lines in the first gate regions and second-threshold metal gate lines in the second gate regions. The first-threshold metal gate lines are formed to have a first threshold voltage and the second-threshold metal gate lines are formed to have a second threshold voltage, where the first and second threshold voltages are sufficiently differentiated so that first-threshold metal gate lines can be turned on or off without turning on or off the second-threshold metal gate lines.

In some embodiments, the method 3900 can further include applying CMODE at stage 3926 (e.g., after stage 3924) to selectively disable one or more gate structures subsequent to gate formation. In some embodiments, the method 3900 can further include applying CPODE at stage 3903 (e.g., before stage 3904) to selectively pre-disable one or more gate regions prior to gate formation.

Some embodiments begin prior to gate formation and after source/drain region etching has left wells in which source/drain structures will be epitaxially grown. Such embodiments can further include, at stage 3901, depositing bottom isolation dielectrics at the bottom of each such well. Such embodiments can further include, at stage 3902, epitaxially growing source/drain structures in the source/drain regions (i.e., on the bottom isolation dielectrics).

The foregoing merely outlines features of embodiments of the disclosure. Various modifications and alterations to the described embodiments will be apparent to those skilled in the art in view of the teachings herein. Those skilled in the art will appreciate that equivalent constructions do not depart from the scope of the present disclosure, and that they may make various changes, substitutions, and alterations herein without departing from the spirit and scope of the present disclosure.

1. A method comprising:
forming, on a semiconductor substrate, a plurality of linear channel regions running in parallel to each other in a first direction;
forming a plurality of metal gate lines running in parallel to each other in a second direction orthogonal to the first direction thereby crossing the plurality of linear channel regions;
etching a plurality of source/drain regions each to lie on a respective portion of one of the plurality of linear channel regions and between a respective two adjacent ones of the plurality of metal gate lines;
depositing a respective growth inhibiting layer in each of a selected subset of the source/drain regions, each respective growth inhibiting layer configured to inhibit epitaxial growth; and
growing an epitaxial layer, such that a source/drain structure grows epitaxially in each of the source/drain regions except for those of the selected subset.

2. The method of claim 1, wherein:
the etching exposes, in each source/drain region, semiconductor material having a first lattice structure;
the respective growth inhibiting layer in each of a selected subset of the source/drain regions is made of a material having a second lattice structure that is epitaxially mismatched to the first lattice structure; and
epitaxial layer is made of a material having a third lattice structure that is epitaxially matched to the first lattice structure to support coherent epitaxial growth.

3. The method of claim 1, further comprising, for each source/drain region of the selected subset of the source/drain regions, subsequent to the growing the epitaxial layer:
removing the respective growth inhibiting layer from the source/drain region; and
filling the source/drain region with an interlayer dielectric (ILD) material.

4. The method of claim 1,
wherein the first direction is an X direction and the second direction is a Y direction, and for each particular source/drain region of the plurality of source/drain regions:
a respective first adjacent source/drain region lies on a respective first adjacent linear channel region adjacent to the particular source/drain region in the positive Y direction;
a respective second adjacent source/drain region lies on a respective second adjacent linear channel region adjacent to the particular source/drain region in the negative Y direction;
a respective first adjacent metal gate line of the respective two adjacent ones of the plurality of metal gate lines is adjacent to the particular source/drain region in the positive X direction; and
a respective second adjacent metal gate line of the respective two adjacent ones of the plurality of metal gate lines is adjacent to the particular source/drain region in the negative X direction; and
further comprising, for each particular source/drain region of the plurality of source/drain regions, gate-etching a portion of each of the respective two adjacent ones of the plurality of metal gate lines to form electrical discontinuities in each of the respective first adjacent metal gate line and the respective second adjacent metal gate line.

5. The method of claim 4, wherein:
for each particular source/drain region of the plurality of source/drain regions, a respective first cut metal gate (CMG) region is defined as a region of the respective two adjacent ones of the plurality of metal gate lines lying between the respective linear channel region and one of the respective first adjacent linear channel region or the respective second adjacent linear channel region; and
the gate-etching comprises forming a CMG cut across both the respective first adjacent metal gate line and the respective second adjacent metal gate line in the respective first CMG region.

6. The method of claim 5, wherein at least one source/drain region of the plurality of source/drain regions extends in the positive or negative Y direction to intersect with the respective first CMG region.

7. The method of claim 5, wherein:
for each particular source/drain region of the plurality of source/drain regions, a respective second CMG region is defined as a region of the respective two adjacent ones of the plurality of metal gate lines lying between the respective linear channel region and the other of the respective first adjacent linear channel region or the respective second adjacent linear channel region;
the CMG cut is a first CMG cut; and
the gate-etching comprises forming a second CMG cut across both the respective first adjacent metal gate line and the respective second adjacent metal gate line in the respective second CMG region.

8. The method of claim 7, wherein at least one source/drain region of the plurality of source/drain regions extends in the positive and negative Y directions to intersect with the respective first CMG region and with the respective second CMG region.

9. The method of claim 5, wherein the gate-etching comprises forming the first CMG cut and/or the second CMG cut as a single contiguous cut across both the respective first adjacent metal gate line and the respective second adjacent metal gate line in the respective first CMG region.

10. A method for fabricating a semiconductor device comprising:
providing a wafer comprising:
a plurality of linear channel regions running in parallel to each other in an X direction, and formed on a substrate to extend in a positive Z direction from the substrate, the Z direction being orthogonal to the X direction; and
a plurality of gate lines running in parallel to each other in a Y direction orthogonal to the X and Z directions, the gate lines made of a gate material and disposed on the linear channel regions to form a network of fin arrangements;
etching a plurality of source/drain regions each to lie on a respective portion of one of the plurality of linear channel regions and between a respective two adjacent ones of the plurality of gate lines;
depositing a respective growth inhibiting layer in each of a selected subset of the source/drain regions, each respective growth inhibiting layer configured to inhibit epitaxial growth; and
growing an epitaxial layer, such that a source/drain structure grows epitaxially in each of the source/drain regions except for those of the selected subset.

11. The method of claim 10, wherein prior to the etching, each of the plurality of linear channel regions comprises at least two silicon-germanium interposer layers each sandwiched between adjacent channel material layers, and further comprising:
subsequent to the etching, replacing the silicon-germanium interposer layers with corresponding oxide interposer layers.

12. The method of claim 10, wherein prior to the growing the epitaxial layer, the gate material is a semiconductor gate material, and further comprising:
subsequent to the growing the epitaxial layer, replacing the semiconductor gate material with a metal gate material to convert the plurality of gate lines to a plurality of metal gate lines.

13. The method of claim 10, further comprising, for each source/drain region of the selected subset of the source/drain regions, subsequent to the growing the epitaxial layer:
removing the respective growth inhibiting layer from the source/drain region; and
filling the source/drain region with an interlayer dielectric (ILD) material.

14. The method of claim 10,
wherein for each particular source/drain region of the plurality of source/drain regions:
respective first and second adjacent source/drain region lie on respective first and second adjacent linear channel regions adjacent to the particular source/drain region in the positive and negative Y directions, respectively; and
respective first and second adjacent gate lines of the respective two adjacent ones of the plurality of gate lines are adjacent to the particular source/drain region in the positive and negative X directions, respectively;
a respective first cut metal gate (CMG) region is defined as a region of the respective two adjacent ones of the plurality of gate lines lying between the respective linear channel region and one of the respective first adjacent linear channel region or the respective second adjacent linear channel region; and
a respective second CMG region is defined as a region of the respective two adjacent ones of the plurality of gate lines lying between the respective linear channel region and the other of the respective first adjacent linear channel region or the respective second adjacent linear channel region; and
further comprising, for each particular source/drain region of the plurality of source/drain regions, gate-etching a portion of each of the respective two adjacent ones of the plurality of metal gate lines to form electrical discontinuities in each of the respective first adjacent metal gate line and the respective second adjacent metal gate line in the respective first CMG region and/or the respective second CMG region.

15. The method of claim 14, wherein the gate-etching comprises forming a contiguous CMG cut across both the respective first adjacent metal gate line and the respective second adjacent metal gate line in the respective first CMG region and/or the respective second CMG region.

16. The method of claim 15, wherein at least one source/drain region of the plurality of source/drain regions extends in the positive and/or negative Y direction to intersect with the respective first CMG region and/or the respective second CMG region.

17. A semiconductor device comprising:
a substrate;
a plurality of linear channel regions formed on the substrate and running parallel to each other in a first direction;
a plurality of metal gate lines formed above the linear channel regions and running parallel to each other in a second direction perpendicular to the first direction, such that the metal gate lines cross over the linear channel regions;
a plurality of source/drain structures formed on the linear channel regions and positioned between the metal gate lines;
first and second cuts in two adjacent metal gate lines located between a selected linear channel region with a selected source/drain structure and a first adjacent linear channel region adjacent to the selected linear channel region in the first direction; and
third and fourth cuts in the two adjacent metal gate lines located between the selected linear channel region with the selected source/drain structure and a second adjacent linear channel region adjacent to the selected linear channel region in an opposite direction to the first direction,
such that the first, second, third, and fourth cuts in the metal gate lines electrically isolate and disable the selected source/drain structure.

18. The semiconductor device of claim 17, wherein the first, second, third, and fourth cuts in the metal gate lines are filled with a dielectric material.

19. The semiconductor device of claim 17, wherein the selected source/drain structure is electrically isolated from the substrate by a bottom isolation dielectric layer disposed beneath the selected source/drain structure.

20. The semiconductor device of claim 17, wherein the cuts in the metal gate lines are aligned with shallow trench isolation (STI) regions in the substrate.
